(19) United States
(12) Patent Application Publication
(10) Pub. No.: US 2024/0014131 A1
(43) Pub. Date: Jan. 11, 2024

(54) SEMICONDUCTOR DEVICE

(71) Applicant: ROHM CO., LTD., Kyoto-shi (JP)

(72) Inventor: Masaki NAGATA, Kyoto-shi (JP)

(73) Assignee: ROHM CO., LTD., Kyoto-shi (JP)

(21) Appl. No.: 18/473,484

(22) Filed: Sep. 25, 2023

Related U.S. Application Data
(63) Continuation of application No. PCT/JP2022/004272, filed on Feb. 3, 2022.

(30) Foreign Application Priority Data
Mar. 26, 2021 (JP) 2021-053751

(51) Int. Cl. H01L 23/528; H01L 29/78; H01L 29/417

(52) U.S. Cl. CPC H01L 23/528; H01L 29/7813; H01L 29/41741

(57) ABSTRACT

A semiconductor device includes a chip having a main surface, a groove structure including a groove formed at the main surface, a source electrode that is embedded in the groove at a bottom side of the groove and that has a projection portion on one side and a projection portion on the other side both of which protrude toward an opening side of the groove, and a gate electrode embedded between a pair of the projection portions at the opening side of the groove, and a source via electrode on one side and a source via electrode on the other side that are connected to the projection portion on the one side and the projection portion on the other side, respectively, on the groove structure.

### CROSS REFERENCE TO RELATED APPLICATIONS

This application is a continuation of International Application No. PCT/JP2022/004272, filed Feb. 3, 2022, which claims priority to Japanese Patent Application No. 2021-053751 filed with the Japan Patent Office on Mar. 26, 2021, the entire disclosure of which are incorporated herein by reference.

### BACKGROUND

### 1. Field of the Disclosure

The present disclosure relates to a semiconductor device.

### 2. Description of the Related Art

United States Patent Application Publication No. 2008/0042172 discloses a semiconductor device including a semiconductor base material, a trench, a gate electrode, and a field electrode. The semiconductor base material has a first surface. The trench is formed at the first surface of the semiconductor base material. The gate electrode is arranged in the trench. The field electrode is arranged under the gate electrode in the trench.

### BRIEF DESCRIPTION OF THE DRAWINGS

FIG. 1 is a plan view showing a semiconductor device according to a first embodiment.

FIG. 2 is a plan view showing a structure of a first main surface of a chip.

FIG. 3 is a plan view in which a main portion of the structure shown in FIG. 2 is enlarged.

FIG. 4 is a plan view in which the main portion of the structure shown in FIG. 3 is further enlarged.

FIG. 5 is a cross-sectional view along line V-V shown in FIG. 4.

FIG. 6 is a cross-sectional view along line VI-VI shown in FIG. 5.

FIG. 7 is a cross-sectional view along line VII-VII shown in FIG. 6.

FIG. 8 is a cross-sectional perspective view of the main portion of the structure shown in FIG. 3.

FIG. 9 is an electric circuit diagram showing a switching circuit.

FIG. 10 is a graph showing switching characteristics when a semiconductor device according to a reference example is applied to the switching circuit shown in FIG. 9.

FIG. 11 is a graph showing switching characteristics when the semiconductor device shown in FIG. 1 is applied to the switching circuit shown in FIG. 9.

FIG. 12 corresponds to FIG. 2, and is a plan view showing a structure of a first main surface of a chip of a semiconductor device according to a second embodiment.

FIG. 13 is a plan view in which a main portion of the structure shown in FIG. 12 is enlarged.

FIG. 14 is a plan view in which the main portion of the structure shown in FIG. 13 is further enlarged.

FIG. 15 corresponds to FIG. 14, and is a plan view showing a structure of a first main surface of a chip of a semiconductor device according to a third embodiment.

FIG. 16 corresponds to FIG. 2, and is a plan view showing a structure of a first main surface of a chip of a semiconductor device according to a fourth embodiment.

FIG. 17 corresponds to FIG. 3, and is a plan view showing a modification of a plurality of trench connection structures.

FIG. 18 corresponds to FIG. 4, and is a plan view showing a modification of a plurality of first source via electrodes and of a plurality of second source via electrodes.

### DETAILED DESCRIPTION OF THE PREFERRED EMBODIMENTS

Embodiments will be hereinafter described in detail with reference to the accompanying drawings. The accompanying drawings are schematic views that are not strictly shown and that do not coincide with each other in scale and the like. The same reference signs are respectively assigned to mutually corresponding constituents in the accompanying drawings, and a repetitive description of each corresponding constituent is omitted or simplified. A description, which has not yet been omitted or not yet been simplified, of a constituent is applied to the constituent a description of which has been omitted or simplified.

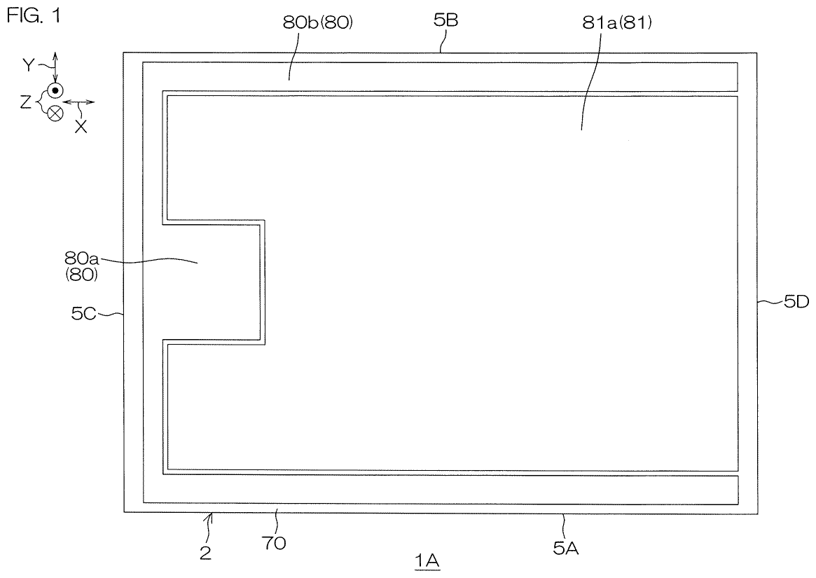

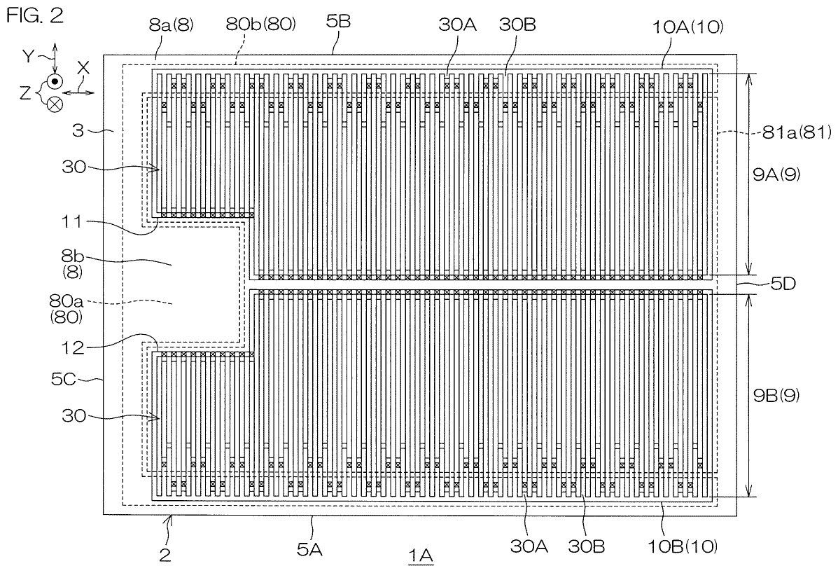

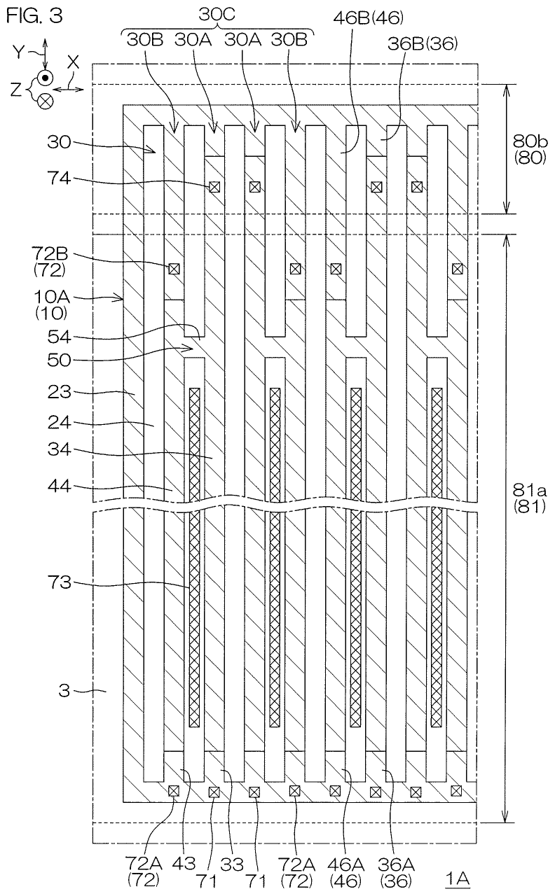

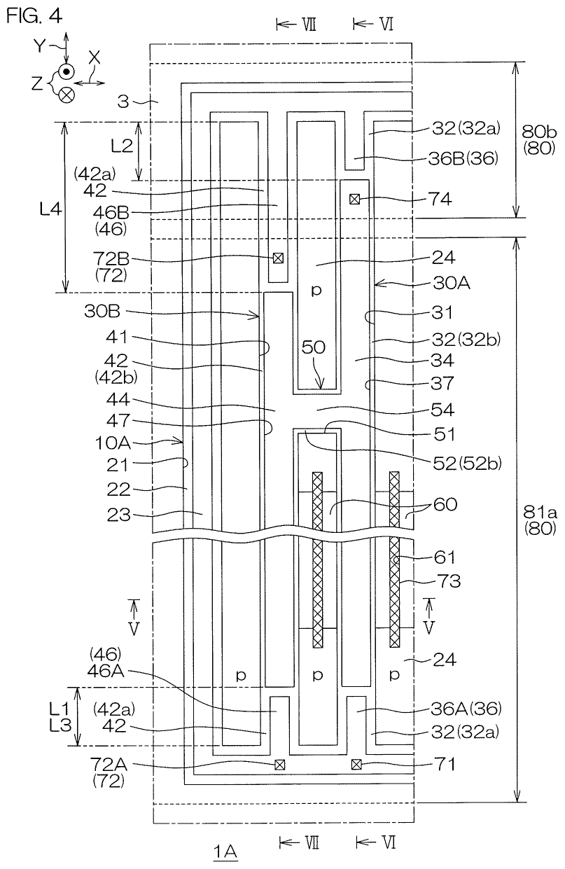

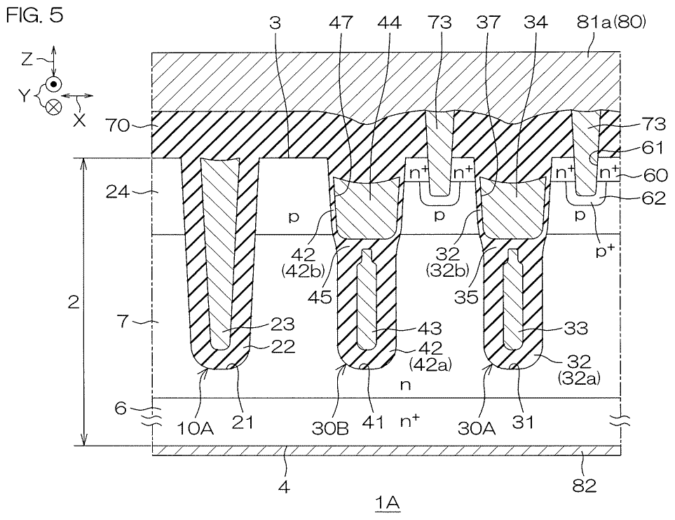

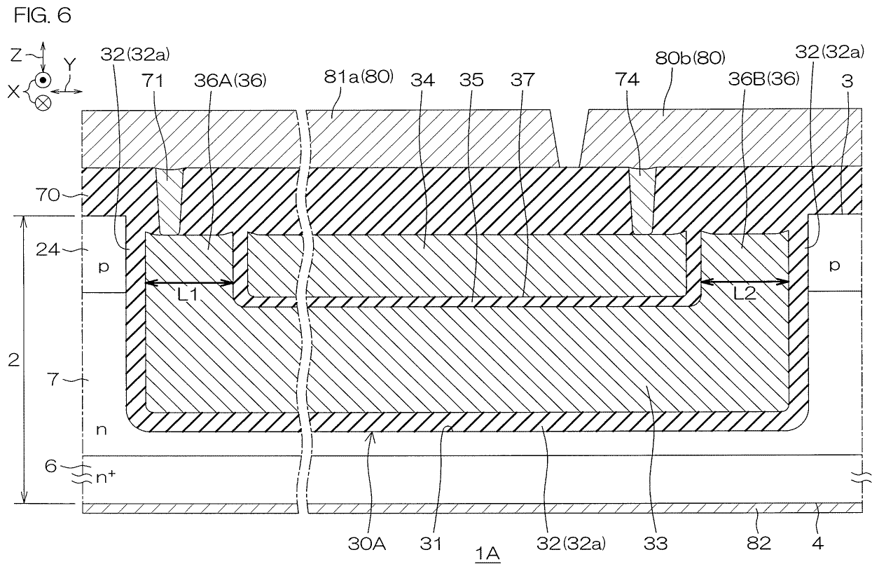

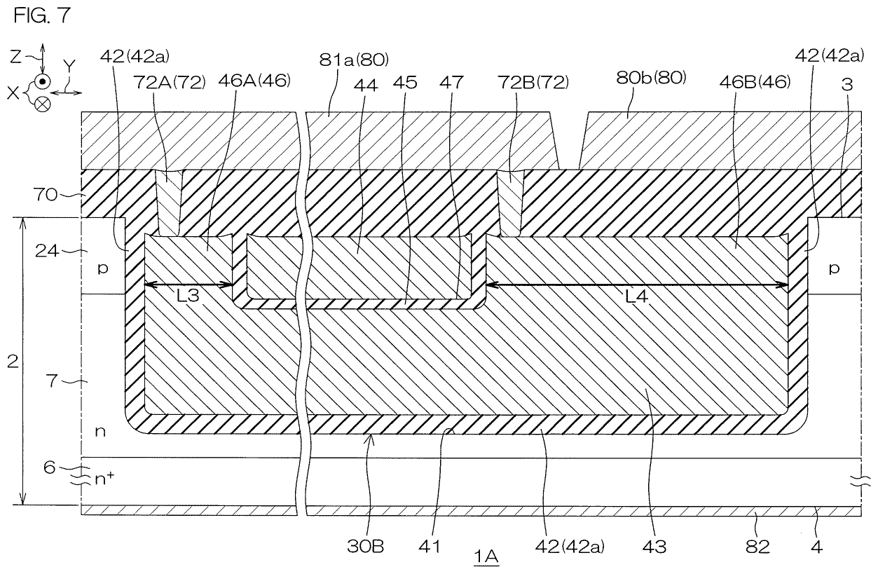

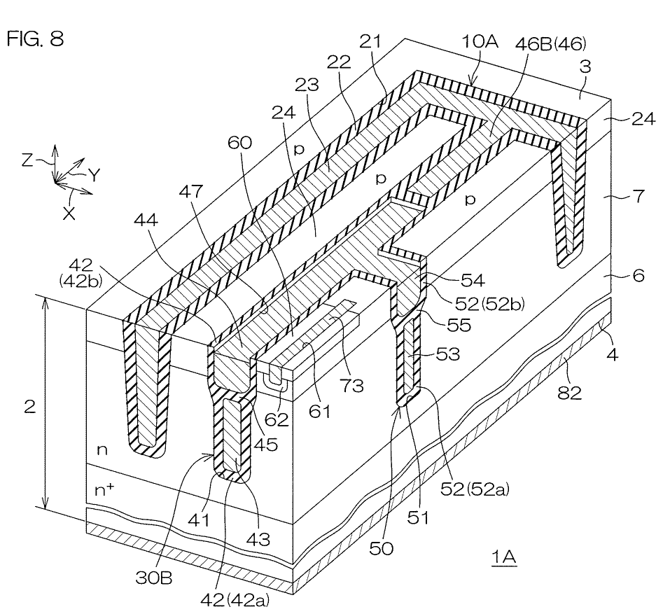

FIG. 1 is a plan view showing a semiconductor device 1A according to a first embodiment. FIG. 2 is a plan view showing a structure of a first main surface 3 of a chip 2. FIG. 3 is a plan view in which a main portion of the structure shown in FIG. 2 is enlarged. FIG. 4 is a plan view in which the main portion of the structure shown in FIG. 3 is further enlarged. FIG. 5 is a cross-sectional view along line V-V shown in FIG. 4. FIG. 6 is a cross-sectional view along line VI-VI shown in FIG. 5. FIG. 7 is a cross-sectional view along line VII-VII shown in FIG. 6. FIG. 8 is a cross-sectional perspective view of the main portion of the structure shown in FIG. 3.

Referring to FIG. 1 to FIG. 8, the semiconductor device 1A is a switching device including a trench insulated-gate type MISFET (Metal Insulator Semiconductor Field Effect Transistor) that is an example of a field-effect transistor in this embodiment.

The semiconductor device 1A includes a silicon-made chip 2 (semiconductor chip) formed in a rectangular parallelepiped shape. The chip 2 includes a first main surface 3 on one side, a second main surface 4 on the other side, and first to fourth side surfaces 5A to 5D that connect the first main surface 3 and the second main surface 4 together. The first main surface 3 and the second main surface 4 are each formed in a quadrangular shape (in detail, rectangular shape) in a plan view seen from their normal directions Z (hereinafter, referred to simply as a “plan view”).

The first side surface 5A and the second side surface 5B extend in a first direction X along the first main surface 3, and face a second direction Y that intersects (in detail, perpendicularly intersects) the first direction X. The first side surface 5A and the second side surface 5B form the long side of the chip 2. The third side surface 5C and the fourth side surface 5D extend in the second direction Y, and face the first direction X. The third side surface 5C and the fourth side surface 5D form the short side of the chip 2.

The semiconductor device 1A includes an n-type (first conductivity type) first semiconductor region 6 formed at a surface layer portion of the second main surface 4 of the chip 2. The first semiconductor region 6 may be referred to as a “drain region.” The first semiconductor region 6 is formed in a layer shape extending along the second main surface 4, and is exposed from the second main surface 4 and from the first to fourth side surfaces 5A to 5D. In this embodiment, the first semiconductor region 6 is formed by an n-type semiconductor substrate (Si substrate).

The semiconductor device 1A includes an n-type second semiconductor region 7 formed at a surface layer portion of the first main surface 3 of the chip 2. The second semiconductor region 7 has an n-type impurity concentration lower than the first semiconductor region 6. The second semiconductor region 7 may be referred to as a “drift region.” The second semiconductor region 7 is formed in a layer shape extending along the first main surface 3, and is exposed from the first main surface 3 and from the first to fourth side surfaces 5A to 5D. The second semiconductor region 7 is electrically connected to the first semiconductor region 6 in the chip 2. The second semiconductor region 7 has a thickness less than the thickness of the first semiconductor region 6. In this embodiment, the second semiconductor region 7 is formed by an n-type epitaxial layer (Si epitaxial layer).

The semiconductor device 1A includes an outer region 8 set at a peripheral edge portion of the first main surface 3. The outer region 8 is a region in which MISFET is not formed. The outer region 8 includes an annular region 8a and a pad region 8b. The annular region 8a extends in an annular shape (in detail, quadrangular annular shape) along a peripheral edge of the first main surface 3 so as to surround an inward portion of the first main surface 3 in a plan view. The pad region 8b is set so as to protrude from the annular region 8a toward the inward portion of the first main surface 3 in a plan view. In this embodiment, the pad region 8b protrudes in a quadrangular shape from a part, which is along a central portion of the third side surface 5C, of the annular region 8a toward an inward portion (fourth side surface 5D side) in a plan view.

The semiconductor device 1A includes a device region 9 set at the inward portion of the first main surface 3. The device region 9 is a region in which the MISFET is formed. In this embodiment, the device region 9 includes a first device region 9A and a second device region 9B. The first device region 9A is set in a region of the second side surface 5B with respect to a line that crosses a central portion of the first main surface 3 in the first direction X in a plan view.

The second device region 9B is set in a region on the first side surface 5A side with respect to the line that crosses the central portion of the first main surface 3 in the first direction X in a plan view. The first device region 9A and the second device region 9B are each set in a polygonal shape along an inner edge of the outer region 8 in a plan view. Hereinafter, the first side surface 5A side is referred to as “one side,” and the second side surface 5B side is referred to as “the other side.”

The semiconductor device 1A includes a trench separation structure 10 that defines the device region 9 in the inward portion of the first main surface 3. The trench separation structure 10 may be referred to as a “groove separation structure.” In this embodiment, the trench separation structure 10 includes a first trench separation structure 10A that defines the first device region 9A and a second trench separation structure 10B that defines the second device region 9B.

The first trench separation structure 10A is formed in a region on the other side with respect to the line that crosses the central portion of the first main surface 3 in the first direction X in a plan view. The first trench separation structure 10A is formed in an annular shape surrounding a part of the first main surface 3 in a plan view, and defines the part of the first main surface 3 as the first device region 9A. The first trench separation structure 10A has a first L-shaped path portion 11 that is bent in the shape of the capital letter L along the pad region 8b at an end portion on the third side surface 5C side in a plan view.

The second trench separation structure 10B is formed at the first main surface 3 at a distance from the first trench separation structure 10A. In this embodiment, the second trench separation structure 10B is formed in a region on the one side with respect to the line that crosses the central portion of the first main surface 3 in the first direction X in a plan view. The second trench separation structure 10B is formed in an annular shape surrounding a part of the first main surface 3 in a plan view, and defines the part of the first main surface 3 as the second device region 9B. The second trench separation structure 10B has a second L-shaped path portion 12 that is bent in the shape of the capital letter L along the pad region 8b at the end portion on the third side surface 5C side in a plan view. The second L-shaped path portion 12 faces the first L-shaped path portion 11 across the part (i.e., the pad region 8b) of the first main surface 3 in the second direction Y.

The plurality of trench separation structures 10 each have a single electrode structure including a separation trench 21, a separation insulating film 22, and a separation electrode 23. The separation trench 21 is formed at the first main surface 3, and defines an inner wall (bottom wall and sidewall) of the trench separation structure 10. The separation trench 21 is formed at a distance from a bottom portion of the second semiconductor region 7 toward the first main surface 3 side. The separation insulating film 22 covers a wall surface of the separation trench 21.

The separation insulating film 22 is formed as a field insulating film that is comparatively thick. The separation insulating film 22 may include a silicon oxide film. The separation electrode 23 is embedded in the separation trench 21 as an integrally-formed element with the separation insulating film 22 between the separation electrode 23 and the separation trench 21. The separation electrode 23 may include conductive polysilicon. A source potential is to be applied to the separation electrode 23.

Hereinafter, a structure formed on the first device region 9A side is described, and a description of a structure formed on the second device region 9B side is omitted. The structure on the second device region 9B side is the same as the structure on the first device region 9A side except that the structure on the second device region 9B side is formed on the first side surface 5A side. In the following description, the structure on the second device region 9B side is obtained by replacing the “first device region 9A” with the “second device region 9B,” and by replacing the “one side (first side surface 5A side)” with the “the other side (second side surface 5B side),” and by replacing the “the other side (second side surface 5B side)” with the “one side (first side surface 5A side).”

The semiconductor device 1A includes a p-type (second conductivity type) body region 24 formed at the surface layer portion of the first main surface 3 in the first device region 9A. The body region 24 is formed at a surface layer portion of the second semiconductor region 7. In detail, the body region 24 is formed at the surface layer portion of the first main surface 3 (second semiconductor region 7) at a distance from the bottom wall of the first trench separation structure 10A. The body region 24 may be formed in the whole area of the surface layer portion of the second semiconductor region 7 in the first device region 9A.

The semiconductor device 1A includes a plurality of trench structures 30 formed at the first main surface 3 in the first device region 9A. The plurality of trench structures 30 are arranged at a distance from each other in the first direction X, and are each formed in a band shape extending in the second direction Y. In other words, the plurality of trench structures 30 are formed in a stripe manner extending in the second direction Y. Preferably, the plurality of trench structures 30 are arranged in the first direction X at substantially equal intervals therebetween. Both end portions in the second direction Y of the plurality of trench structures 30 are connected to the first trench separation structure 10A.

Referring to FIG. 3 and FIG. 4, the plurality of trench structures 30 include a plurality of first trench structures 30A, and a plurality of second trench structures 30B having structures different from the plurality of first trench structures 30A. The plurality of first trench structures 30A are each formed in a band shape extending in the second direction Y. The plurality of second trench structures 30B are arranged at a distance from the plurality of first trench structures 30A in the first direction X so as to face at least one first trench structure 30A.

The plurality of second trench structures 30B are each formed in a band shape extending in substantially parallel with the plurality of first trench structures 30A. Each of the second trench structures 30B has a width substantially equal to that of each of the first trench structures 30A with respect to the first direction X. Each of the second trench structures 30B has a length substantially equal to that of each of the first trench structures 30A, which adjoin each other in the first direction X, with respect to the second direction Y.

The number and arrangement of the first trench structures 30A and the number and arrangement of the second trench structures 30B are optional as long as each of the second trench structures 30B faces at least one first trench structure 30A in the first direction X. The number and arrangement of the first trench structures 30A and the number and arrangement of the second trench structures 30B are adjusted in accordance with electrical characteristics to be achieved. The number of the second trench structures 30B may be equal to or more than the number of the first trench structures 30A, or may be less than the number of the first trench structures 30A.

In this embodiment, the plurality of trench structures 30 include a plurality of trench units 30C that form periodic arrangement patterns of the plurality of first and second trench structures 30A and 30B at the first main surface 3 (first device region 9A). The plurality of trench units 30C each include a pair of first and second trench structures 30A and 30 that adjoin each other in the first direction X as a minimum unit, and are arranged in the first direction X. Each of the trench units 30C may include at least one first trench structure 30A and two second trench structures 30B between which at least one first trench structure 30A is sandwiched from the first direction X.

In this embodiment, each of the trench units 30C includes a plurality of (in this embodiment, two) first trench structures 30A adjoining each other in the first direction X. As a matter of course, each of the trench units 30C may be formed of one of the first trench structures 30A in the first direction X and other one of the second trench structures 30B in the first direction X. In other words, the plurality of second trench structures 30B may be arranged alternately with the plurality of first trench structures 30A in the first direction X in a manner of sandwiching the single first trench structure 30A. Referring to FIG. 4 to FIG. 8, a concrete configuration of the single first trench structure 30A and a concrete configuration of the single second trench structure 30B will be hereinafter described.

The first trench structure 30A includes a first trench 31, a first insulating film 32, a first source electrode 33, a first gate electrode 34, and a first intermediate insulating film 35. The first trench 31 is formed at the first main surface 3, and defines a wall surface (sidewall and bottom wall) of the first trench structure 30A. The first trench 31 passes through the body region 24, and is formed at a distance from the bottom portion of the second semiconductor region 7 toward the first main surface 3 side. The first trench 31 has a depth substantially equal to that of the separation trench 21. The first trench 31 has both end portions that communicate with the trench separation structure 10 (separation trench 21).

The first insulating film 32 covers an opening side wall surface and a bottom side wall surface of the first trench 31. The opening side wall surface is a wall surface placed on the opening side of the first trench 31 with respect to a bottom portion of the body region 24. The bottom side wall surface is a wall surface placed on the bottom wall side of the first trench 31 with respect to the bottom portion of the body region 24. The first insulating film 32 is connected to the separation insulating film 22 in a communication portion between the separation trench 21 and the first trench 31. In this embodiment, the first insulating film 32 includes a first lower insulating film 32a and a first upper insulating film 32b that differs in thickness from the first lower insulating film 32a.

The first lower insulating film 32a covers the bottom side wall surface of the first trench 31. The first lower insulating film 32a is contiguous to the second semiconductor region 7 exposed from the wall surface of the first trench 31. The first lower insulating film 32a covers the opening side wall surface and the bottom side wall surface of the first trench 31 in both end portions of the first trench 31, and is connected to the separation insulating film 22 of the trench separation structure 10. The first lower insulating film 32a may include silicon oxide. The first lower insulating film 32a is formed as a comparatively-thick field insulating film in the same way as the separation insulating film 22.

The first upper insulating film 32b covers the opening side wall surface of the first trench 31. The first upper insulating film 32b has a portion covering the second semiconductor region 7 and a portion covering the body region 24. The covering area of the first upper insulating film 32b with respect to the body region 24 is larger than the covering area of the first upper insulating film 32b with respect to the second semiconductor region 7. The first upper insulating film 32b may include silicon oxide. The first upper insulating film 32b is formed as a gate insulating film that is thinner than the first lower insulating film 32a.

The first source electrode 33 is embedded in the first trench 31 on the bottom wall side with the first insulating film 32 (in detail, first lower insulating film 32a) between the first source electrode 33 and the first trench 31. The first source electrode 33 faces the second semiconductor region 7 across the first lower insulating film 32a. The first source electrode 33 is formed in a band shape extending in the second direction Y in a plan view, and is formed in a pillar shape extending in the normal direction Z in a cross-sectional view.

The first source electrode 33 is connected to the separation electrode 23 in the communication portion between the separation trench 21 and the first trench 31. A connection portion between the separation electrode 23 and the first source electrode 33 may be regarded as a part of the separation electrode 23 or as a part of the first source electrode 33. The first source electrode 33 is formed as a field electrode to which a source potential is to be applied. The first source electrode 33 may include conductive polysilicon.

The first source electrode 33 includes a plurality of first projection portions 36 that protrude from the bottom wall side to the opening side of the first trench 31. The plurality of first projection portion 36 includes a first projection portion 36A on one side (first side surface 5A side) and a first projection portion 36B on the other side (second side surface 5B side) distant from the first projection portion 36A on the one side in the second direction Y. In this embodiment, the pair of first projection portions 36A and 36B are formed at both end portions of the first trench 31, respectively, and are pulled out toward the opening side of the first trench 31 across the first lower insulating film 32a.

The pair of first projection portions 36A and 36B extend in the second direction Y, and are connected to the separation electrode 23 in the communication portion between the separation trench 21 and the first trench 31. The pair of first projection portions 36A and 36B define a first recess 37 on the opening side of the first trench 31 with the wall surface of the first trench 31. The first recess 37 is defined in a band shape extending in the second direction Y in a plan view. With respect to a longitudinal direction of the first trench 31 (second direction Y), the first projection portion 36A on the one side has a first length L1, and the first projection portion 36B on the other side has a second length L2 (L1≈L2) that is substantially equal to the first length L1.

The first gate electrode 34 is embedded in the first trench 31 at the opening side with the first insulating film 32 (in detail, first upper insulating film 32b) between the first gate electrode 34 and the first trench 31. In detail, the first gate electrode 34 is embedded in the first recess 37 between the pair of first projection portions 36A and 36B at the opening side of the first trench 31. The first gate electrode 34 faces both the body region 24 and the second semiconductor region 7 across the first upper insulating film 32b.

The first gate electrode 34 is formed in a band shape extending in the second direction Y in a plan view. The first gate electrode 34 has a thickness less than the thickness of the first source electrode 33 in the normal direction Z. The first gate electrode 34 has an upper end portion placed on the bottom wall side of the first trench 31 with respect to the first main surface 3. The first gate electrode 34 may include conductive polysilicon.

The first intermediate insulating film 35 is interposed between the first source electrode 33 and the first gate electrode 34 in the first trench 31, and electrically insulates the first source electrode 33 and the first gate electrode 34. The first intermediate insulating film 35 is continuous with the first insulating film 32 (first lower insulating film 32a and first upper insulating film 32b) in the first trench 31. Preferably, the first intermediate insulating film 35 is thicker than the first upper insulating film 32b. The first intermediate insulating film 35 may include silicon oxide.

The second trench structure 30B includes a second trench 41, a second insulating film 42, a second source electrode 43, a second gate electrode 44, and a second intermediate insulating film 45. The second trench 41 is formed in the first main surface 3 at a distance from the first trench 31 in the first direction X, and defines a wall surface (sidewall and bottom wall) of the second trench structure 30B. The second trench 41 passes through the body region 24, and is formed at a distance from the bottom portion of the second semiconductor region 7 toward the first main surface 3 side. The second trench 41 has a depth substantially equal to that of the first trench 31. The second trench 41 has both end portions that communicate with the trench separation structure 10 (separation trench 21).

The second insulating film 42 covers an opening side wall surface and a bottom side wall surface of the second trench 41. The opening side wall surface is a wall surface placed on the opening side of the second trench 41 with respect to the bottom portion of the body region 24. The bottom side wall surface is a wall surface placed on the bottom wall side of the second trench 41 with respect to the bottom portion of the body region 24. The second insulating film 42 is connected to the separation insulating film 22 in the communication portion between the separation trench 21 and the second trench 41. In this embodiment, the second insulating film 42 includes a second upper insulating film 42b that differs in thickness from the second lower insulating film 42a and the second lower insulating film 42a.

The second lower insulating film 42a covers the bottom side wall surface of the second trench 41. The second lower insulating film 42a is contiguous to the second semiconductor region 7 exposed from the wall surface of the second trench 41. The second lower insulating film 42a covers the opening side wall surface and the bottom side wall surface of the second trench 41 in both end portions of the second trench 41, and is connected to the separation insulating film 22 of the trench separation structure 10. The second lower insulating film 42a may include silicon oxide. The second lower insulating film 42a is formed as a comparatively-thick field insulating film in the same way as the first lower insulating film 32a.

The second upper insulating film 42b covers the opening side wall surface of the second trench 41. The second upper insulating film 42b has a portion covering the second semiconductor region 7 and a portion covering the body region 24. The covering area of the second upper insulating film 42b with respect to the body region 24 is larger than the covering area of the second upper insulating film 42b with respect to the second semiconductor region 7. The second upper insulating film 42b may include silicon oxide. The second upper insulating film 42b is formed as a gate insulating film that is thinner than the second lower insulating film 42a in the same way as the first upper insulating film 32b.

The second source electrode 43 is embedded in the second trench 41 on the bottom wall side with the second insulating film 42 (in detail, second lower insulating film 42a) between the second source electrode 43 and the second trench 41. The second source electrode 43 faces the second semiconductor region 7 across the second lower insulating film 42a. The second source electrode 43 is formed in a band shape extending in the second direction Y in a plan view, and is formed in a pillar shape extending in the normal direction Z in a cross-sectional view.

The second source electrode 43 is connected to the separation electrode 23 in the communication portion between the separation trench 21 and the second trench 41. A connection portion between the separation electrode 23 and the second source electrode 43 may be regarded as a part of the separation electrode 23, or may be regarded as a part of the second source electrode 43. The second source electrode 43 is formed as a field electrode to which a source potential is to be applied in the same way as the first source electrode 33. The second source electrode 43 may include conductive polysilicon.

The second source electrode 43 includes a plurality of second projection portions 46 that protrude from the bottom wall side to the opening side of the second trench 41. The plurality of second projection portions 46 include a second projection portion 46A on one side (first side surface 5A side) and a second projection portion 46B on the other side (second side surface 5B side) distant from the second projection portion 46A on the one side in the second direction Y. The pair of second projection portions 46A and 46B are formed at both end portions of the second trench 41, respectively, and are pulled out to the opening side of the second trench 41 across the second lower insulating film 42a. The pair of second projection portions 46A and 46B extend in the second direction Y, and are connected to the separation electrode 23 in the communication portion between the separation trench 21 and the second trench 41.

The pair of second projection portions 46A and 46B have mutually-different lengths, respectively, in the longitudinal direction of the second trench 41 (second direction Y). The second projection portion 46A on the one side has a third length L3 (L1≈L3) that is substantially equal to the first length L1 of the first projection portion 36A on the one side with respect to the second direction Y. The second projection portion 46B on the other side has a fourth length L4 (L1≈L2≈L3≠L4) differing from the third length L3 of the second projection portion 46A on the one side with respect to the second direction Y. In detail, the fourth length L4 exceeds the third length L3 (L3<L4). In other words, the fourth length L4 of the second projection portion 46B on the other side exceeds the first length L1 and the second length L2 (L1≈L2<L4).

The second projection portion 46A on the one side faces the first projection portion 36A on the one side across a part of the chip 2 (in detail, second semiconductor region 7 and body region 24), and does not face the first gate electrode 34. The second projection portion 46B on the other side faces the first projection portion 36B on the other side and the first gate electrode 34 across a part of the chip 2 (in detail, the second semiconductor region 7 and body region 24).

The pair of second projection portions 46A and 46B define a second recess 47 on the opening side of the second trench 41 with the wall surface of the second trench 41. The second recess 47 is defined in a band shape extending in the second direction Y in a plan view. The second recess 47 has a length less than the length of the first recess 37 with respect to the second direction Y.

The second gate electrode 44 is embedded in the second trench 41 at the opening side with the second insulating film 42 (in detail, second upper insulating film 42b) between the second gate electrode 44 and the second trench 41. In detail, the second gate electrode 44 is embedded in the second recess 47 between the pair of second projection portions 46A and 46B at the opening side of the second trench 41. The second gate electrode 44 faces the body region 24 and the second semiconductor region 7 across the second upper insulating film 42b. The second gate electrode 44 is formed in a band shape extending in the second direction Y in a plan view. In this embodiment, the second gate electrode 44 faces the first gate electrode 34 adjoining in the first direction X, and does not face the pair of first projection portions 36A and 36B.

The second gate electrode 44 has a length shorter than the first gate electrode 34 with respect to the second direction Y. The second gate electrode 44 has a thickness less than the thickness of the second source electrode 43 with respect to the normal direction Z. The second gate electrode 44 has an upper end portion placed on the bottom wall side of the second trench 41 with respect to the first main surface 3. The second gate electrode 44 may include conductive polysilicon.

The second intermediate insulating film 45 is interposed between the second source electrode 43 and the second gate electrode 44 in the second trench 41, and electrically insulates the second source electrode 43 and the second gate electrode 44. The second intermediate insulating film 45 is continuous with the second insulating film 42 (second lower insulating film 42a and second upper insulating film 42b) in the second trench 41. Preferably, the second intermediate insulating film 45 is thicker than the second upper insulating film 42b in the same way as the first intermediate insulating film 35. The second intermediate insulating film 45 may include silicon oxide.

The semiconductor device 1A includes a trench connection structure 50 connected to the second trench structure 30B. The trench connection structure 50 may be referred to as a “groove connection structure.” The trench connection structure 50 is pulled out from the second trench structure 30B toward the first trench structure 30A, and is connected to the first trench structure 30A. In this embodiment, the plurality of trench connection structures 50 are each pulled out from the plurality of second trench structures 30B toward the adjoining first trench structure 30A so as to be connected to the adjoining first trench structure 30A. In this embodiment, the trench connection structure 50 is not formed in a region between the pair of first trench structures 30A adjoining each other, and is not formed in a region between the pair of second trench structures 30B adjoining each other.

Each of the trench connection structures 50 extends in a direction (in detail, first direction X perpendicular to second direction Y) intersecting a direction (second direction Y) in which the second trench structure 30B extends. The plurality of trench connection structures 50 are each pulled out from an arbitrary region between the pair of second projection portions 46A and 46B of the second trench structure 30B toward an arbitrary region between the pair of first projection portions 36A and 36B of the adjacent first trench structure 30A.

In this embodiment, the plurality of trench connection structures 50 are each arranged at a position adjacent to the second projection portion 46B on the other side with respect to the second projection portion 46A on the one side. In other words, the plurality of trench connection structures 50 are each arranged at a position at which a distance from the second projection portion 46B on the other side is less than a distance from the second projection portion 46A on the one side. In this embodiment, the plurality of trench connection structures 50 are each arranged on the same line extending in the second direction Y. The trench connection structure 50 has a width substantially equal to a width in the first direction X of the second trench structure 30B (first trench structure 30A) with respect to the second direction Y. A concrete configuration of the single trench connection structure 50 will be hereinafter described with reference to FIG. 4 and FIG. 8.

The trench connection structure 50 includes a connection trench 51, a connection insulating film 52, a source connection electrode 53, a gate connection electrode 54, and an intermediate connection insulating film 55. The connection trench 51 is formed in the first main surface 3, and forms a wall surface (sidewall and bottom wall) of the trench connection structure 50. The connection trench 51 passes through the body region 24, and is formed at a distance from the bottom portion of the second semiconductor region 7 toward the first main surface 3 side.

The connection trench 51 has a depth substantially equal to that of the second trench 41 (first trench 31). The connection trench 51 communicates with the first trench 31 and the second trench 41. In detail, the connection trench 51 communicates with a region between the pair of first projection portions 36A and 36B of the first trench 31 and with a region between the pair of second projection portions 46A and 46B of the second trench 41.

The connection insulating film 52 covers an opening side wall surface and a bottom side wall surface of the connection trench 51. The opening side wall surface is a wall surface placed on the opening side of the connection trench 51 with respect to the bottom portion of the body region 24. The bottom side wall surface is a wall surface placed on the bottom wall side of the connection trench 51 with respect to the bottom portion of the body region 24. The connection insulating film 52 is connected to the second insulating film 42 in a communication portion between the second trench 41 and the connection trench 51, and is connected to the first insulating film 32 in a communication portion between the first trench 31 and the connection trench 51. In this embodiment, the connection insulating film 52 includes a lower connection insulating film 52a and an upper connection insulating film 52b having a thickness differing from that of the lower connection insulating film 52a.

The lower connection insulating film 52a covers the bottom side wall surface of the connection trench 51. The lower connection insulating film 52a is contiguous to the second semiconductor region 7 exposed from the wall surface of the connection trench 51. The lower connection insulating film 52a is connected to the second lower insulating film 42a in the communication portion between the second trench 41 and the connection trench 51, and is connected to the first lower insulating film 32a in the communication portion between the first trench 31 and the connection trench 51. The lower connection insulating film 52a may include silicon oxide. The lower connection insulating film 52a is formed as a comparatively-thick field insulating film in the same way as the second lower insulating film 42a (first lower insulating film 32a).

The upper connection insulating film 52b covers the opening side wall surface of the connection trench 51. The upper connection insulating film 52b has a portion covering the second semiconductor region 7 and a portion covering the body region 24. The covering area of the upper connection insulating film 52b with respect to the body region 24 is larger than the covering area of the upper connection insulating film 52b with respect to the second semiconductor region 7.

The upper connection insulating film 52b is connected to the second upper insulating film 42b in the communication portion between the second trench 41 and the connection trench 51, and is connected to the first upper insulating film 32b in the communication portion between the first trench 31 and the connection trench 51. The upper connection insulating film 52b may include silicon oxide. The upper connection insulating film 52b is formed as a gate insulating film that is thinner than the lower connection insulating film 52a in the same way as the second upper insulating film 42b (first upper insulating film 32b).

The source connection electrode 53 is embedded in the connection trench 51 on the bottom wall side with the connection insulating film 52 (in detail, lower connection insulating film 52a) between the source connection electrode 53 and the connection trench 51. The source connection electrode 53 faces the second semiconductor region 7 across the lower connection insulating film 52a. The source connection electrode 53 is formed in a band shape extending in the first direction X in a plan view, and is formed in a pillar shape extending in the normal direction Z in a cross-sectional view.

The source connection electrode 53 is connected to the second source electrode 43 in the communication portion between the second trench 41 and the connection trench 51, and is connected to the first source electrode 33 in the communication portion between the first trench 31 and the connection trench 51. In other words, the source connection electrode 53 is electrically connected to the first source electrode 33 and to the second source electrode 43. Also, the source connection electrode 53 is electrically connected to the separation electrode 23 through the first source electrode 33 and through the second source electrode 43. The source connection electrode 53 is formed as a field electrode, to which a source potential is to be applied, together with the first source electrode 33 and the second source electrode 43. The source connection electrode 53 may include conductive polysilicon.

The gate connection electrode 54 is embedded in the connection trench 51 at the opening side with the connection insulating film 52 (in detail, upper connection insulating film 52b) between the gate connection electrode 54 and the connection trench 51. The gate connection electrode 54 faces the body region 24 and the second semiconductor region 7 across the upper connection insulating film 52b. The gate connection electrode 54 is formed in a band shape extending in the first direction X in a plan view. The gate connection electrode 54 overlaps with the whole area of the source connection electrode 53 in a plan view, and does not expose the source connection electrode 53. The gate connection electrode 54 is connected to the second gate electrode 44 in the communication portion between the second trench 41 and the connection trench 51, and is connected to the first gate electrode 34 in the communication portion between the first trench 31 and the connection trench 51.

In other words, the gate connection electrode 54 is electrically connected to the first gate electrode 34 and to the second gate electrode 44. In this embodiment, the gate connection electrode 54 transmits a gate potential applied to the first gate electrode 34 to the second gate electrode 44. The gate connection electrode 54 has a thickness less than the thickness of the source connection electrode 53 in the normal direction Z. The gate connection electrode 54 has an upper end portion placed on the bottom wall side of the connection trench 51 with respect to the first main surface 3. The gate connection electrode 54 may include conductive polysilicon.

The intermediate connection insulating film 55 is interposed between the source connection electrode 53 and the gate connection electrode 54 in the connection trench 51, and electrically insulates the source connection electrode 53 and the gate connection electrode 54. The intermediate connection insulating film 55 is continuous with the lower connection insulating film 52a and with the upper connection insulating film 52b in the connection trench 51.

The intermediate connection insulating film 55 is connected to the second intermediate insulating film 45 in the communication portion between the second trench 41 and the connection trench 51, and is connected to the first intermediate insulating film 35 in the communication portion between the first trench 31 and the connection trench 51. Preferably, the intermediate connection insulating film 55 is thicker than the upper connection insulating film 52b in the same way as the second intermediate insulating film 45 (first intermediate insulating film 35). The intermediate connection insulating film 55 may include silicon oxide.

The semiconductor device 1A includes a plurality of source regions 60 each of which is formed in a region between the plurality of trench structures 30 in the surface layer portion of the body region 24. Each of the source regions 60 has an n-type impurity concentration higher than the second semiconductor region 7, and is formed at a distance from the bottom portion of the body region 24.

Each of the source regions 60 is formed in a region between the first trench structure 30A and the second trench structure 30B that adjoin each other, in a region between the first trench structures 30A that adjoin each other, and in a region between the second trench structures 30B that adjoin each other. The plurality of source regions 60 form a channel controlled by both the first trench structure 30A and the second trench structure 30B between the second semiconductor region 7 and the source region 60.

In this embodiment, the plurality of source regions 60 are each formed in a band shape extending in the second direction Y in a part, which is placed more inwardly than the plurality of trench connection structures 50, of the first main surface 3. In detail, the plurality of source regions 60 are formed in regions on the first projection portion 36A side and the second projection portion 46A side each of which is the one side with respect to the plurality of trench connection structures 50, and are not formed in regions on the first projection portion 36B side and the second projection portion 46B side each of which is the other side with respect to the plurality of trench connection structures 50. The plurality of source regions 60 are connected to the first and second trench structures 30A and 30B in the first direction X, and are formed at a distance from the trench connection structures 50 in the second direction Y.

The semiconductor device 1A includes a plurality of contact holes 61 formed in the first main surface 3 so as to pass through the plurality of source regions 60, respectively. The plurality of contact holes 61 are each formed at a distance from the bottom portion of the body region 24. The plurality of contact holes 61 are each formed in a region between the plurality of trench structures 30. In detail, the plurality of contact holes 61 are each formed in a region between the first trench structure 30A and the second trench structure 30B that adjoin each other, in a region between the first trench structures 30A that adjoin each other, and in a region between the second trench structures 30B that adjoin each other.

In this embodiment, the plurality of contact holes 61 are each formed in a band shape extending in the second direction Y in a part, which is placed more inwardly than the plurality of trench connection structures 50, of the first main surface 3. In detail, the plurality of contact holes 61 are formed in regions on the first projection portion 36A side and the second projection portion 46A side each of which is the one side with respect to the plurality of trench connection structures 50, and are not formed in regions on the first projection portion 36B side and the second projection portion 46B side each of which is the other side with respect to the trench connection structures 50.

The plurality of contact holes 61 are formed at a distance from the first and second trench structures 30A and 30B in the first direction X, and are formed at a distance from the plurality of trench connection structures 50 in the second direction Y. The arrangement pattern of the plurality of contact holes 61 is optional. The plurality of contact holes 61 may be formed with intervals therebetween in the second direction Y in regions between the plurality of trench structures 30.

The semiconductor device 1A includes a plurality of p-type contact regions 62 formed in regions along the plurality of contact holes 61, respectively, in the surface layer portion of the body region 24. Each of the contact regions 62 has a p-type impurity concentration higher than the body region 24, and covers the bottom wall of each of the contact holes 61 at a distance from the bottom portion of the body region 24. The plurality of contact regions 62 may cover sidewalls of the plurality of contact holes 61.

The semiconductor device 1A includes main surface insulating film 70 (insulating film) covering the first main surface 3. The main surface insulating film 70 may be referred to as an “interlayer insulating film.” The main surface insulating film 70 may have a layered structure in which a plurality of insulating films are stacked together, or may have a single-layer structure consisting of a single insulating film. The main surface insulating film 70 may include at least one among a silicon oxide film, a silicon nitride film, and a silicon oxynitride film. The main surface insulating film 70 covers the plurality of trench separation structures 10, the plurality of first trench structures 30A, the plurality of second trench structures 30B, and the plurality of trench connection structures 50 on the first main surface 3. The main surface insulating film 70 may cover the whole area of the first main surface 3.

The semiconductor device 1A includes a plurality of first source via electrodes 71 each of which is connected to the first source electrode 33 corresponding to one of the first source via electrodes 71 on the plurality of first trench structures 30A. Each of the first source via electrodes 71 passes through the main surface insulating film 70, and is connected to the first projection portion 36A corresponding thereto on one side, and is not connected to the first projection portion 36B on the other side. In this embodiment, the plurality of first source via electrodes 71 are each connected to the first projection portion 36A on the one side that corresponds in one-to-one correspondence.

The plurality of first source via electrodes 71 are arranged with intervals between the plurality of first source via electrodes 71 in the first direction X in a plan view, and face each other in the first direction X. The plurality of first source via electrodes 71 may be each connected to the first projection portion 36A on the one side that corresponds in one-to-many correspondence. The plurality of first source via electrodes 71 are not necessarily required to be arranged on the same line extending in the first direction X in a plan view, and may be arranged so as to deviate from each other in the second direction Y.

The semiconductor device 1A includes a plurality of second source via electrodes 72 each of which is connected to the second source electrode 43 corresponding to one of the second source via electrodes 72 on the plurality of second trench structures 30B. The plurality of second source via electrodes 72 pass through the main surface insulating film 70, and are each connected to the pair of second projection portions 46A and 46B corresponding to one of the second source via electrodes 72. In detail, the plurality of second source via electrodes 72 include the second source via electrode 72A on the one side connected to the second projection portion 46A on the one side and the second source via electrode 72B on the other side connected to the second projection portion 46B on the other side.

In this embodiment, the plurality of second source via electrodes 72A on the one side are each connected to the second projection portion 46A on the one side that corresponds in one-to-one correspondence. The plurality of second source via electrodes 72A on the one side are arranged at a distance from each other in the first direction X, and face each other in the first direction X. The plurality of second source via electrodes 72A on the one side are arranged at a distance from the plurality of first source via electrodes 71 in the first direction X, and face the plurality of first source via electrodes 71 in the first direction X.

The plurality of second source via electrodes 72A on the one side may be each connected to the second projection portion 46A on the one side that corresponds in one-to-many correspondence. The plurality of second source via electrodes 72A on the one side are not necessarily required to be arranged on the same line extending in the first direction X in a plan view, and may be arranged so as to deviate from each other in the second direction Y. Also, the plurality of second source via electrodes 72A on the one side may be arranged so as to deviate from the plurality of first source via electrodes 71 in the second direction Y.

In this embodiment, the plurality of second source via electrodes 72B on the other side are each connected to the second projection portion 46B on the other side that corresponds in one-to-one correspondence. The plurality of second source via electrodes 72B on the other side are arranged at a distance from each other in the first direction X, and face each other in the first direction X. The plurality of second source via electrodes 72B on the other side may be each connected to the second projection portion 46B on the other side that corresponds in one-to-many correspondence. The plurality of second source via electrodes 72B on the other side are not necessarily required to be arranged on the same line extending in the first direction X in a plan view, and may be arranged so as to deviate from each other in the second direction Y.

The plurality of second source via electrodes 72B on the other side are each connected to the second projection portion 46B on the other side at a position closer to the second gate electrode 44 corresponding thereto than to an end portion of the second trench structure 30B corresponding thereto in a plan view. In other words, the plurality of second source via electrodes 72B on the other side are each connected to the second projection portion 46B on the other side corresponding thereto so that the distance between the second source via electrode 72B and the second gate electrode 44 becomes less than the distance between the second source via electrode 72B and the end portion of the second trench structure 30B. Also, the plurality of second source via electrodes 72B on the other side are closer to the second gate electrode 44 than to the separation electrode 23 in a plan view.

The plurality of second source via electrodes 72B on the other side face the first gate electrode 34 adjoining in the first direction X in a plan view, and do not face the first projection portion 36B on the other side. In other words, if a line that crosses the first gate electrode 34 in the first direction X is set within a range between the first projection portion 36B on the other side and the second gate electrode 44 in a plan view, the second source via electrode 72B on the other side is arranged on this line.

The semiconductor device 1A includes a plurality of third source via electrodes 73 connected to the plurality of source regions 60 on the first main surface 3. The plurality of third source via electrodes 73 pass through the main surface insulating film 70, and are embedded in the plurality of contact holes 61, respectively. The plurality of third source via electrodes 73 are each electrically connected to the source region 60 and to the contact region 62 in each of the contact holes 61. In this embodiment, the plurality of third source via electrodes 73 are each formed in a band shape extending in the second direction Y in a part, which is placed more inwardly than the plurality of trench connection structures 50, of the first main surface 3, and do not face the trench connection structure 50 in the first direction X.

The semiconductor device 1A includes a plurality of gate via electrodes 74 that are each connected to the first gate electrode 34 corresponding to one of the gate via electrodes 74 on the plurality of first trench structures 30A. The plurality of gate via electrodes 74 pass through the main surface insulating film 70, and are each connected to the first gate electrode 34 corresponding thereto. The plurality of gate via electrodes 74 are each connected to the first gate electrode 34 in one-to-one correspondence, and is not connected to the second gate electrode 44. In other words, the semiconductor device 1A does not include the gate via electrode 74 that is connected to the second gate electrode 44 on the second trench structure 30B. The plurality of gate via electrodes 74 are electrically connected to the second gate electrode 44 through the first gate electrode 34 and through the gate connection electrode 54.

The plurality of gate via electrodes 74 are arranged at a distance from each other in the first direction X, and face each other in the first direction X. The plurality of gate via electrodes 74 face the plurality of first source via electrodes 71 in the second direction Y. The plurality of gate via electrodes 74 may be each connected to each of the first gate electrodes 34 in one-to-many correspondence. The plurality of gate via electrodes 74 are not necessarily required to be arranged on the same line extending in the first direction X in a plan view, and may be arranged so as to deviate from each other in the second direction Y.

The plurality of gate via electrodes 74 are arranged at positions closer to the first projection portion 36B on the other side than to the trench connection structure 50 in a plan view. In other words, the plurality of gate via electrodes 74 are each connected to the first gate electrode 34 corresponding thereto so that the distance between the gate via electrode 74 and the first projection portion 36B on the other side is less than the distance between the gate via electrode 74 and the trench connection structure 50. In this embodiment, if a line that crosses the second source via electrode 72B on the other side in the first direction X in a plan view is set, the plurality of gate via electrodes 74 are arranged at positions that are closer to the first projection portion 36B on the other side than to this line.

The plurality of gate via electrodes 74 face the second projection portion 46B on the other side adjoining in the first direction X in a plan view, and do not face the second gate electrode 44. In other words, if a line that crosses the first gate electrode 34 in the first direction X is set within a range between the first projection portion 36B on the other side and the second gate electrode 44 (second source via electrode 72B on the other side) in a plan view, the gate via electrode 74 is arranged on this line.

The semiconductor device 1A includes a gate wiring electrode 80 that is arranged above the plurality of gate via electrodes 74 and that transmits a gate potential. In detail, the gate wiring electrode 80 is arranged on the main surface insulating film 70. The gate wiring electrode 80 includes a gate pad electrode 80a and a gate finger electrode 80b. The gate pad electrode 80a is a terminal electrode that is externally connected to an electroconductive connection member (for example, bonding wire or electroconductive plate). The gate pad electrode 80a is formed in a quadrangular shape on a part along the central portion of the third side surface 5C in a plan view.

The gate pad electrode 80a overlaps with the pad region 8b of the outer region 8 in a plan view. The gate pad electrode 80a is arranged at a distance from the first trench separation structure 10A (first device region 9A) and the second trench separation structure 10B (second device region 9B) toward the pad region 8b side in a plan view. The gate pad electrode 80a does not overlap with the plurality of first and second trench structures 30A and 30B in a plan view.

The gate finger electrode 80b is pulled out from the gate pad electrode 80a onto the main surface insulating film 70. The gate finger electrode 80b extends in a band shape along the peripheral edge of the first main surface 3 so as to define an inward region including the first and second device regions 9A and 9b from a plurality of directions in a plan view. In this embodiment, the gate finger electrode 80b extends in a band shape along the first to third side surfaces 5A to 5C so as to define an inward region from three directions in a plan view. The gate finger electrode 80b may extend in a band shape (preferably, in quadrangular annular shape) along the first to fourth side surfaces 5A to 5D so as to define an inward region from four directions in a plan view.

The gate finger electrode 80b extends along the first and second trench separation structures 10A and 10 so as to intersect (in detail, perpendicularly intersect) the end portions of the plurality of first and second trench structures 30A and 30B in a plan view. The gate finger electrode 80b overlaps with the plurality of separation electrodes 23, the plurality of first projection portions 36B on the other side, the plurality of first gate electrodes 34, and the plurality of second projection portions 46B on the other side in a plan view, and does not overlap with the second gate electrode 44.

The gate finger electrode 80b is connected to the plurality of gate via electrodes 74. A gate potential applied to the gate pad electrode 80a is transmitted to the plurality of first gate electrodes 34 through the gate finger electrode 80b and through the plurality of gate via electrodes 74. A gate potential applied to the plurality of first gate electrodes 34 is transmitted to the plurality of second gate electrodes 44 through the plurality of trench connection structures 50.

The semiconductor device 1A includes a source wiring electrode 81 that is arranged above the plurality of first to third source via electrodes 71 to 73 and that transmits a source potential. The source wiring electrode 81 is arranged at the same layer as the gate wiring electrode 80 at a distance from the gate wiring electrode 80, and faces the gate wiring electrode 80 in a lateral direction along the first main surface 3. In detail, the source wiring electrode 81 is arranged on the main surface insulating film 70. The source wiring electrode 81 includes a source pad electrode 81a. The source pad electrode 81a is a terminal electrode that is externally connected to an electroconductive connection member (for example, bonding wire or electroconductive plate).

The source pad electrode 81a is arranged in a region defined by the gate wiring electrode 80 in a plan view, and overlaps with the first and second device regions 9A and 9b in a plan view. In this embodiment, the source pad electrode 81a is formed in a polygonal shape having a concave portion hollowed from a central portion of the side along the third side surface 5C toward the fourth side surface 5D side so as to match the gate pad electrode 80a in a plan view.

The source pad electrode 81a overlaps with the plurality of first trench separation structures 10A, the plurality of second trench separation structures 10B, the plurality of first trench structures 30A, the plurality of second trench structures 30B, and the plurality of trench connection structures 50 in a plan view. In detail, the source pad electrode 81a overlaps with the plurality of first projection portions 36A on the one side, the plurality of pairs of second projection portions 46A and 46B, the plurality of first gate electrodes 34, and the plurality of second gate electrodes 44 in a plan view, and does not overlap with the plurality of first projection portions 36B on the other side.

The source pad electrode 81a is connected to the plurality of first to third source via electrodes 71 to 73. A source potential applied to the source pad electrode 81a is transmitted to the plurality of separation electrodes 23, the plurality of first source electrodes 33, the plurality of second source electrodes 43, and the plurality of source regions 60.

The semiconductor device 1A includes a drain electrode 82 covering the second main surface 4. In this embodiment, the drain electrode 82 covers the whole area of the second main surface 4 so as to be continuous with the first to fourth side surfaces 5A to 5D, and is electrically connected to the first semiconductor region 6.

As described above, the semiconductor device 1A includes the chip 2, the second trench structure 30B (groove structure), and the plurality of second source via electrodes 72. The chip 2 has the first main surface 3. The second trench structure 30B includes the second trench 41 (groove), the second source electrode 43 (source electrode), and the second gate electrode 44 (gate electrode).

The second trench 41 is formed in the first main surface 3. The second source electrode 43 is embedded in the second trench 41 at its bottom side. The second source electrode 43 includes the second projection portions 46A and 46B (projection portions) on the one side (in this embodiment, the first side surface 5A side) and on the other side (in this embodiment, the second side surface 5B side). The second projection portions 46A and 46B on the one side and on the other side protrude from the bottom side of the second trench 41 toward the opening side of the second trench 41.

The second gate electrode 44 is embedded between the pair of second projection portions 46A and 46B at the opening side of the second trench 41. The plurality of second source via electrodes 72 include the second source via electrodes 72A and 72B (source via electrodes) on the one side and on the other side. The second source via electrodes 72A and 72B on the one side and on the other side are connected to the second projection portions 46A and 46B on the one side and on the other side, respectively, on the second trench structure 30B.

This structure makes it possible to exactly regulate source resistance Rs by adjusting the distance between the pair of second projection portions 46A and 46B or the distance between the pair of second source via electrodes 72A and 72B. Therefore, it is possible to provide the semiconductor device 1A having appropriate source resistance Rs.

Preferably, the semiconductor device 1A does not have the gate via electrode 74 to be connected to the second gate electrode 44 on the second trench structure 30B. This structure makes it possible to adjust the distance between the pair of second projection portions 46A and 46B or the distance between the pair of second source via electrodes 72A and 72B without being subject to restrictions on the design rule of the gate via electrode 74.

Preferably, the semiconductor device 1A includes the gate wiring electrode 80 (gate wiring) and the source wiring electrode 81 (source wiring). Preferably, the gate wiring electrode 80 is arranged above the second trench structure 30B so as not to overlap with the second gate electrode 44 in a plan view. Preferably, the source wiring electrode 81 is arranged above the second trench structure 30B so as to overlap with the pair of second projection portions 46A and 46B and the second gate electrode 44 in a plan view, and is connected to the pair of second source via electrodes 72A and 72B.

This structure makes it possible to electrically connect the source wiring electrode 81 to the pair of second source via electrodes 72A and 72B without being subject to restrictions on the design rule of the gate via electrode 74. Preferably, the source wiring electrode 81 overlaps with the whole area of the second gate electrode 44 in a plan view. The gate wiring electrode 80 may overlap with either one or both of the pair of second projection portions 46A and 46B in a plan view. In this embodiment, the gate wiring electrode 80 overlaps with the second projection portion 46B on the other side in a plan view, and does not overlap with the second projection portion 46A on the one side.

Preferably, the semiconductor device 1A includes the trench connection structure 50 (groove connection structure) connected to the second trench structure 30B. Preferably, the trench connection structure 50 includes the connection trench 51 (connection groove) and the gate connection electrode 54. The connection trench 51 is formed in the first main surface 3 so as to communicate with the second trench 41. The gate connection electrode 54 is embedded in the connection trench 51 so as to be connected to the second gate electrode 44. This structure makes it possible to impart a gate potential to the second gate electrode 44 through the gate connection electrode 54.

Preferably, the trench connection structure 50 includes the source connection electrode 53 embedded in the connection trench 51 at the bottom side so as to be connected to the second source electrode 43. In this case, preferably, the gate connection electrode 54 is embedded in the connection trench 51 at the opening side. In this structure, the gate connection electrode 54 may face the whole area of the source connection electrode 53 in a plan view.

The semiconductor device 1A may have the second projection portion 46B on the other side that is longer than the second projection portion 46A on the one side. This structure makes it possible to exactly regulate source resistance Rs by adjusting the length of the second projection portion 46B on the other side. In this structure, the second source via electrode 72B on the other side may be connected to the second projection portion 46B on the other side at a position close to the second gate electrode 44. In this case, it is possible to adjust the distance between the pair of second source via electrodes 72A and 72B by use of the comparatively long second projection portion 46B on the other side.

The semiconductor device 1A may have a combinations structure including the chip 2, the first trench structure 30A (first groove structure), the second trench structure 30B (second groove structure), the first source via electrode 71, the plurality of second source via electrodes 72, and the gate via electrode 74. The chip 2 has the first main surface 3. The first trench structure 30A includes the first trench 31 (first groove), the first source electrode 33, and the first gate electrode 34.

The first trench 31 is formed in the first main surface 3. The first source electrode 33 is embedded in the first trench 31 at the bottom side. The first source electrode 33 includes the first projection portions 36A and 36B on the one side (in this embodiment, the first side surface 5A side) and on the other side (in this embodiment, the second side surface 5B side). The first projection portions 36A and 36B on the one side and on the other side protrude from the bottom side toward the opening side of the first trench 31. The first gate electrode 34 is embedded between the pair of first projection portions 36A and 36B at the opening side of the first trench 31.

The second trench structure 30B includes the second trench 41 (second groove), the second source electrode 43, and the second gate electrode 44. The second trench 41 adjoins the first trench 31, and is formed in the first main surface 3. The second source electrode 43 is embedded in the second trench 41 at the bottom side. The second source electrode 43 includes the second projection portions 46A and 46B on the one side and on the other side. The second projection portions 46A and 46B on the one side and on the other side protrude from the bottom side toward the opening side of the second trench 41. The second gate electrode 44 is embedded between the pair of second projection portions 46A and 46B at the opening side of the second trench 41.

The first source via electrode 71 is connected to the first projection portion 36A on the one side on the first trench structure 30A. The plurality of second source via electrodes 72 include the second source via electrodes 72A and 72B on the one side and on the other side. The second source via electrodes 72A and 72B on the one side and on the other side are connected to the second projection portions 46A and 46B on the one side and on the other side, respectively, on the second trench structure 30B. The gate via electrode 74 is connected to the first gate electrode 34 on the first trench structure 30A.

This structure makes it possible to exactly regulate source resistance Rs by adjusting the distance between the pair of second projection portions 46A and 46B and the distance between the pair of second source via electrodes 72A and 72B in a form including the first trench structure 30A and the second trench structure 30B. Therefore, it is possible to provide the semiconductor device 1A having appropriate source resistance Rs.

Also, this structure enables the second trench structure 30B to have the second source electrode 43 whose current path is made shorter than the first trench structure 30A. In other words, the first trench structure 30A is enabled to have a first source resistance component Rs1, whereas the second trench structure 30B is enabled to have a second source resistance component Rs2 (Rs2<Rs1) less than the first source resistance component Rs1. Each of the first and second source resistance components Rs1 and Rs2 is one component of the source resistance Rs. Thereby, it is possible to reduce the source resistance Rs.

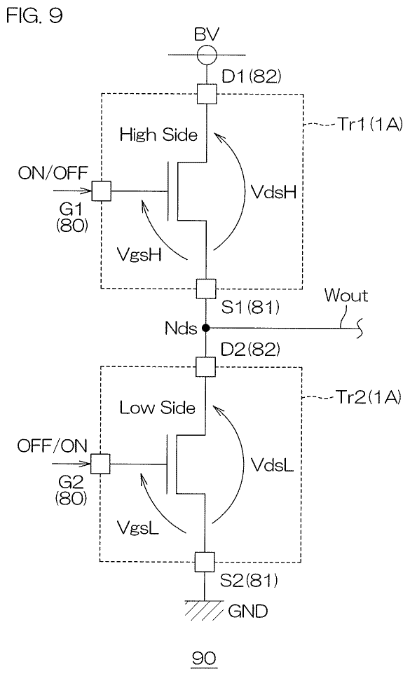

Also, this structure makes it possible to fulfill effects described with reference to FIG. 9 to FIG. 11 as below. FIG. 9 is an electric circuit diagram showing a switching circuit 90. The switching circuit 90 includes a high-side first transistor Tr1, a low-side second transistor Tr2 connected in series with the first the transistor Tr1, and an output wiring Wout connected to a connection portion between the first transistor Tr1 and the second transistor Tr2. The semiconductor device 1A according to the first embodiment is applied to the first transistor Tr1 and to the second transistor Tr2.

The first transistor Tr1 includes a first gate G1 (gate wiring electrode 80), a first source S1 (source wiring electrode 81), and a first drain D1 (drain electrode 82). The first drain D1 is electrically connected to a high potential (for example, power supply voltage BV). The first gate G1 forms a first source S1 and a first gate-source voltage VgsH, and the first drain D1 forms a first source S1 and a first drain-source voltage VdsH.

The second transistor Tr2 includes a second gate G1 (gate wiring electrode 80), a second source G2 (source wiring electrode 81), and a second drain D2 (drain electrode 82). The second drain D2 is electrically connected to the first source S1, and forms a drain-source node Nds. The second source S2 is electrically connected to a low potential (for example, ground). The second gate G2 forms a second source S2 and a second gate-source voltage VgsL, and the second drain D2 forms a second source S2 and a second drain-source voltage VdsL.

The output wiring Wout is connected to the drain-source node Nds. The second transistor Tr2 is controlled to be in an OFF state when the first transistor Tr1 is controlled to be in an ON state. The second transistor Tr2 is controlled to be in an ON state when the first transistor Tr1 is controlled to be in an OFF state. An electric current generated by the on-off control of the first and second transistors Tr1 and Tr2 is allowed to flow from the first transistor Tr1 to the output wiring Wout, or is allowed to flow from the output wiring Wout to the second transistor Tr2.

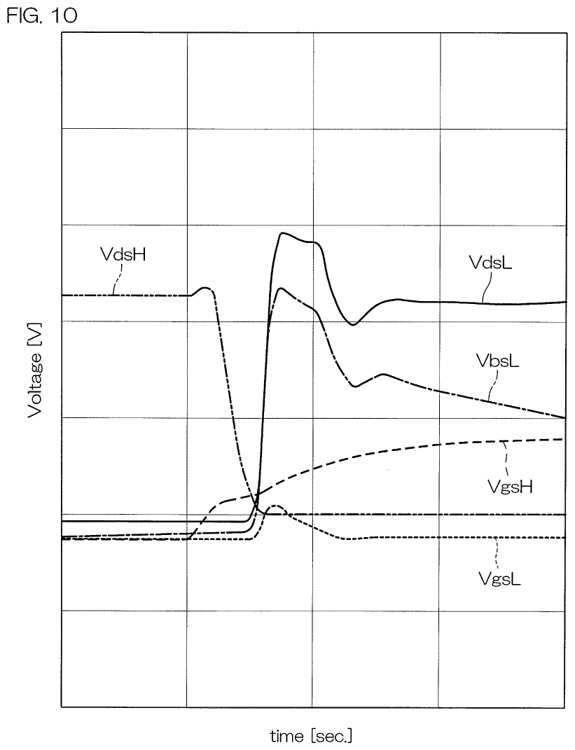

FIG. 10 is a graph showing switching characteristics when a semiconductor device according to a reference example is applied to the switching circuit 90 shown in FIG. 9. In FIG. 10, the vertical axis represents voltage [V], and the horizontal axis represents time [sec]. The semiconductor device according to the reference example has the same structure as the semiconductor device 1A according to the first embodiment except that the plurality of trench structures 30 include only the plurality of first trench structures 30A and do not include the second trench structure 30B and the trench connection structure 50. In other words, in the semiconductor device according to the reference example, source resistance Rs is comparatively high from the fact that the second trench structure 30B is not present. Other detailed description of the semiconductor device according to the reference example is omitted.

FIG. 10 shows a waveform of the first drain-source voltage VdsH of the high-side first transistor Tr1 and a waveform of the first gate-source voltage VgsH. Also, FIG. 10 shows a waveform of the second drain-source voltage VdsL of the low-side second transistor Tr2 and a waveform of the second gate-source voltage VgsL. Also, FIG. 10 shows a waveform of the third drain-source voltage VbsL between the second semiconductor region 7 of the low-side second transistor Tr2 and the plurality of trench structures 30 (in detail, first source electrode 33).

When the high-side first transistor Tr1 is controlled from an OFF state to an ON state, and, as a result, the first drain-source voltage VdsH falls, the second and third drain-source voltages VdsL and VbsL of the low-side second transistor Tr2 rise. The third drain-source voltage VbsL is raised to a value exceeding ½ of the power supply voltage BV. A peak part of the second drain-source voltage VdsL and a peak part of the third drain-source voltage VbsL are each clamped.

In the semiconductor device according to the reference example, the third drain-source voltage VbsL shows steep rise characteristics because of comparatively high source resistance Rs, and therefore the width of a depletion layer spreading from the plurality of trench structures 30 (first trench structure 30A) becomes insufficient. Therefore, a voltage (electric field) concentrates in the vicinity of the plurality of trench structures 30 in the second semiconductor region 7, and, as a result, a breakdown voltage VB decreases, and a leakage current increases. As a result, a peak part of the second drain-source voltage VdsL is clamped.

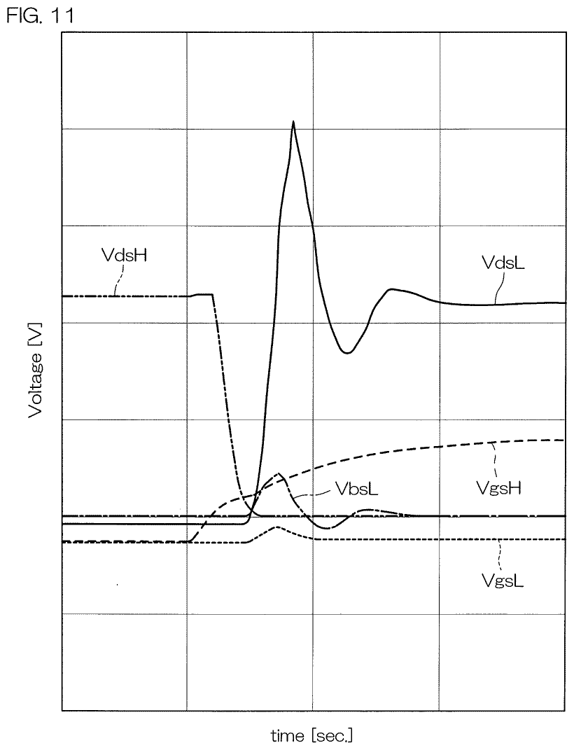

FIG. 11 is a graph showing switching characteristics when the semiconductor device 1A shown in FIG. 1 is applied to the switching circuit 90 shown in FIG. 9. In FIG. 11, the vertical axis represents voltage [V], and the horizontal axis represents time [sec]. FIG. 11 shows a waveform of the first drain-source voltage VdsH, a waveform of the first gate-source voltage VgsH, a waveform of the second drain-source voltage VdsL, a waveform of the second gate-source voltage VgsL, and a waveform of the third drain-source voltage VbsL in the same way as FIG. 10.

When the high-side first transistor Tr1 is controlled from an OFF state to an ON state, and, as a result, the first drain-source voltage VdsH falls, the second and third drain-source voltages VdsL and VbsL of the low-side second transistor Tr2 rise.

In the semiconductor device 1A, the clamp of the peak part of the second drain-source voltage VdsL and the clamp of the peak part of the third drain-source voltage VbsL are restrained, unlike the semiconductor device according to the reference example. Also, in the semiconductor device 1A, a rapid increase of the third drain-source voltage VbsL is restrained. The third drain-source voltage VbsL is restrained to be less than ½ of the power supply voltage BV.

In the semiconductor device 1A, the second trench structure 30B has the second source electrode 43 whose current path is made shorter than the first trench structure 30A. In other words, the first trench structure 30A has a first source resistance component Rs1, and the second trench structure 30B has a second source resistance component Rs2 (Rs2<Rs1) less than the first source resistance component Rs1.

In the semiconductor device 1A, the source resistance Rs is reduced in this manner, and therefore it is possible to make the width of the depletion layer spreading from the plurality of first trench structures 30A and from the plurality of second trench structures 30B wider than in the semiconductor device according to the reference example. This makes it possible to restrain voltage concentration (electric field concentration) in the vicinity of both the plurality of first trench structures 30A and the plurality of second trench structures 30B in the second semiconductor region 7. As a result, it is possible to restrain a decrease of the breakdown voltage VB, and it is possible to restrain a leakage current. Also, it is possible to restrain the clamp of the second drain-source voltage VdsL.

Preferably, the semiconductor device 1A does not have the gate via electrode 74 to be connected to the second gate electrode 44 on the second trench structure 30B. This structure makes it possible to adjust the distance between the pair of second projection portions 46A and 46B or the distance between the pair of second source via electrodes 72A and 72B without being subject to restrictions on the design rule of the gate via electrode 74.

Preferably, the semiconductor device 1A includes the source wiring electrode 81 (source wiring) connected to the first source via electrode 71 and the pair of second source via electrodes 72A and 72B and the gate wiring electrode 80 connected to the gate via electrode 74 (gate wiring). Preferably, the source wiring electrode 81 is arranged above both the first trench structure 30A and the second trench structure 30B so as to overlap with the first projection portion 36A on the one side and with the pair of second projection portions 46A and 46B in a plan view. Preferably, the gate via electrode 74 is arranged on the first trench structure 30A so as to overlap with the first gate electrode 34 in a plan view.

Preferably, in this structure, the source wiring electrode 81 overlaps with the first gate electrode 34 and with the second gate electrode 44 in a plan view. Preferably, the source wiring electrode 81 overlap with the whole area of the second gate electrode 44 in a plan view, and the gate wiring electrode 80 does not overlap with the second gate electrode 44 in a plan view.

Preferably, the semiconductor device 1A includes the trench connection structure 50 (groove connection structure) connected to the first trench structure 30A and to the second trench structure 30B. The trench connection structure 50 includes the connection trench 51 (connection groove) and the gate connection electrode 54. The connection trench 51 is formed in the first main surface 3 so as to communicate with the first trench 31 and with the second trench 41. The gate connection electrode 54 is embedded in the connection trench 51 so as to be connected to the first gate electrode 34 and to the second gate electrode 44. This structure makes it possible to impart a gate potential from the first gate electrode 34 to the second gate electrode 44 through the gate connection electrode 54.

Preferably, in this structure, the trench connection structure 50 includes the source connection electrode 53 embedded in the connection trench 51 at the bottom side so as to be connected to the first source electrode 33 and to the second source electrode 43. Preferably, in this case, the gate connection electrode 54 is embedded in the connection trench 51 at the opening side. In this structure, the gate connection electrode 54 may face the whole area of the source connection electrode 53 in a plan view.

Preferably, in the semiconductor device 1A, the second projection portion 46B on the other side is formed longer than the second projection portion 46A on the one side. This structure makes it possible to exactly regulate the source resistance Rs by adjusting the length of the second projection portion 46B on the other side. Preferably, in this case, the second projection portion 46A on the one side faces the first projection portion 36A on the one side across the chip 2, and the second projection portion 46B on the other side faces the first projection portion 36B on the other side and the first gate electrode 34 across the chip 2.

In these structures, the second source via electrode 72B on the other side may be connected to the second projection portion 46B on the other side at a position close to the second gate electrode 44. In this case, it is possible to adjust the distance between the pair of second source via electrodes 72A and 72B by use of the comparatively-long second projection portion 46B on the other side.

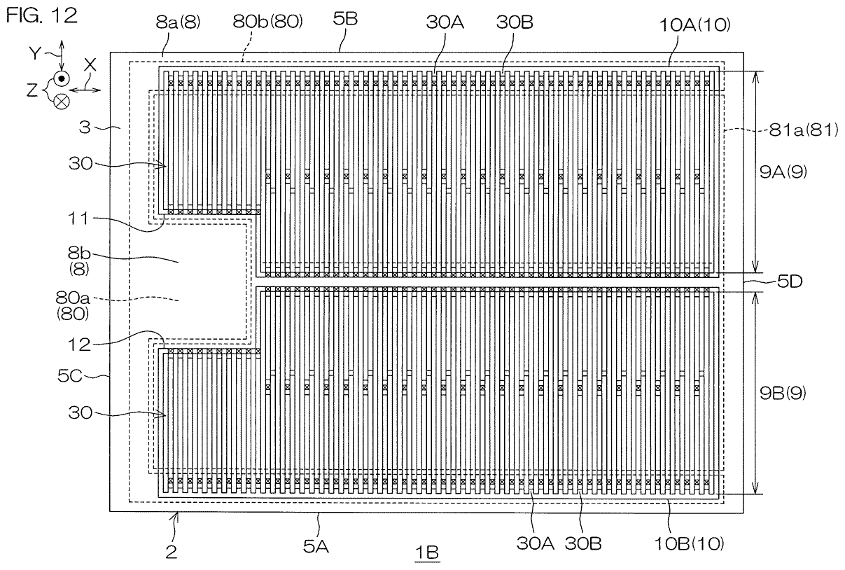

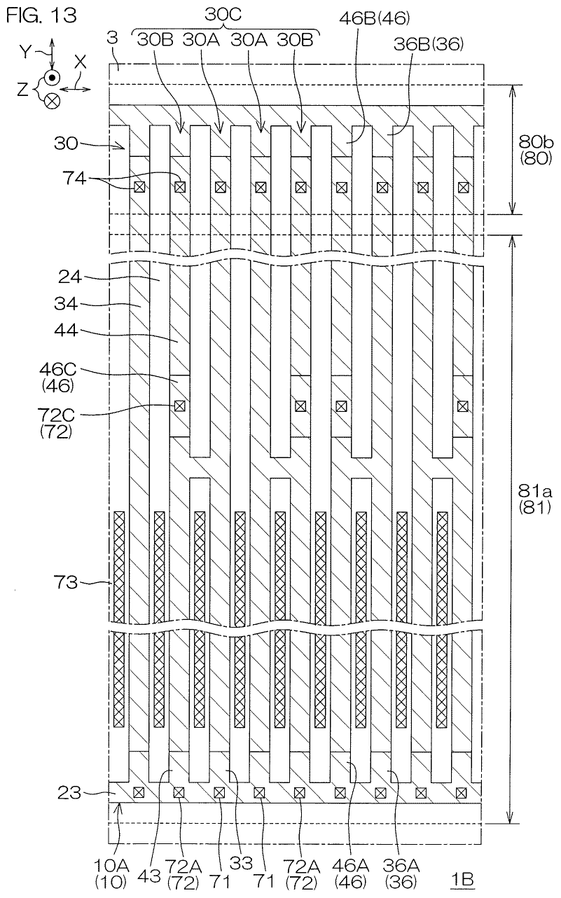

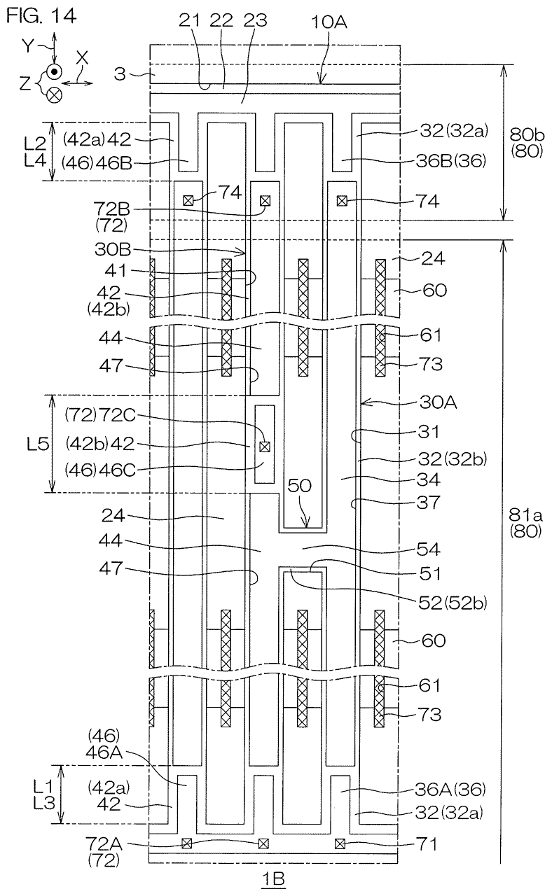

FIG. 12 corresponds to FIG. 2, and is a plan view showing a structure of the first main surface 3 of the chip 2 of a semiconductor device 1B according to the second embodiment. FIG. 13 is a plan view in which a main portion of the structure shown in FIG. 12 is enlarged. FIG. 14 is a plan view in which the main portion of the structure shown in FIG. 13 is further enlarged.

The semiconductor device 1B includes the chip 2, the first semiconductor region 6, the second semiconductor region 7, the first trench separation structure 10A, the second trench separation structure 10B, the plurality of first trench structures 30A, the plurality of second trench structures 30B, the plurality of trench connection structures 50, the plurality of source regions 60, the plurality of contact holes 61, the plurality of contact regions 62, the main surface insulating film 70, the plurality of first source via electrodes 71, the plurality of second source via electrodes 72, the plurality of third source via electrodes 73, the plurality of gate via electrodes 74, the gate wiring electrode 80, the source wiring electrode 81, and the drain electrode 82 in the same way as in the first embodiment.

In this embodiment, the plurality of second trench structures 30B include the second trench 41, the second insulating film 42, the second source electrode 43, the plurality of second gate electrodes 44, and the plurality of second intermediate insulating films 45. The second source electrode 43 includes the plurality of second projection portions 46 that protrude from the bottom wall side toward the opening side of the second trench 41.

The plurality of second projection portions 46 include the second projection portion 46A on the one side (first side surface 5A side), the second projection portion 46B on the other side (second side surface 5B side), and the second projection portion 46C on the inward side placed between the second projection portion 46A on the one side and the second projection portion 46B on the other side. In other words, the second projection portion 46C on the inward side is placed on the other side (second side surface 5B side) with respect to the second projection portion 46A on the one side, and is placed on the one side (second side surface 5A side) with respect to the second projection portion 46B on the other side.

The second projection portions 46A and 46B on the one side and on the other side are formed at both end portions of the second trench 41, respectively, and are pulled out to the opening side of the second trench 41 across the second lower insulating film 42a. The second projection portions 46A and 46B on the one side and on the other side extend in the second direction Y, and are each connected to the separation electrode 23 in the communication portion between the separation trench 21 and the second trench 41. The second projection portions 46A and 46B on the one side and on the other side face the first projection portions 36A and 36B on the one side and on the other side across a part of the chip 2, and do not face the first gate electrode 34 of the first trench structure 30A.

The second projection portion 46C on the inward side is formed at an intermediate portion of the second trench 41, and is pulled out to the opening side of the second trench 41 across the second lower insulating film 42a. The second projection portion 46C on the inward side faces the first gate electrode 34 of the first trench structure 30A across a part of the chip 2, and does not face the first projection portions 36A and 36B on the one side and on the other side. The plurality of second projection portions 46A to 46C define the plurality of second recesses 47 on the opening side of the second trench 41 with the wall surface of the second trench 41.

The second projection portion 46C on the inward side defines the second recess 47 on the one side with the second projection portion 46A on the one side and the wall surface of the second trench 41. The second projection portion 46C on the inward side defines the second recess 47 on the other side with the second projection portion 46B on the other side and the wall surface of the second trench 41. The plurality of second recesses 47 are each defined in a band shape extending in the second direction Y in a plan view. Each of the second recesses 47 has a length less than the length of the first recess 37 with respect to the second direction Y.

In this embodiment, the second projection portion 46C on the inward side has a length differing from each length of the second projection portions 46A and 46B on the one side and on the other side with respect to the longitudinal direction (second direction Y) of the second trench 41. The second projection portions 46A and 46B on the one side and on the other side have a third length L3 and a fourth length L4 (L1≈L2≈L3≈L4), respectively, each of which is substantially equal to the first length L1 of the first projection portion 36A on the one side with respect to the second direction Y. The second projection portion 46C on the inward side has a fifth length L5 (L3≈L4<L5) exceeding the third length L3 (fourth length L4) with respect to the second direction Y. As a matter of course, the fifth length L5 is optional, and may be equal to or less than the third length L3 (fourth length L4) (L5≤L3≈L4).

The plurality of second gate electrodes 44 are each embedded in the second trench 41 at the opening side with the second insulating film 42 (in detail, second upper insulating film 42b) between the second gate electrodes 44 and the second trench 41. In detail, the second gate electrodes 44 are embedded in the plurality of second recesses 47 between the plurality of second projection portions 46A to 46C, respectively, at the opening side of the second trench 41. Each of the second gate electrodes 44 faces the body region 24 and the second semiconductor region 7 across the second upper insulating film 42b.

The plurality of second gate electrodes 44 are each formed in a band shape extending in the second direction Y in a plan view. In this embodiment, each of the second gate electrodes 44 faces the first gate electrode 34 adjoining in the first direction X, and does not face the pair of first projection portions 36A and 36B. The plurality of second gate electrodes 44 are shorter than the first gate electrode 34 with respect to the second direction Y.

The plurality of second intermediate insulating films 45 are each interposed between the second source electrode 43 and the plurality of second gate electrodes 44 in the second trench 41, and electrically insulate the second source electrode 43 and the plurality of second gate electrodes 44. The plurality of second intermediate insulating films 45 are continuous with the second insulating film 42 (second lower insulating film 42a and second upper insulating film 42b) in the second trench 41.

The plurality of trench connection structures 50 are each pulled out from the plurality of second trench structures 30B toward the adjoining first trench structure 30A, and are each connected to the adjoining first trench structure 30A. In this embodiment, the plurality of trench connection structures 50 are not formed in a region between the pair of first trench structures 30A adjoining each other and in a region between the pair of first trench structures 30B adjoining each other. In this embodiment, the plurality of trench connection structures 50 are each pulled out from an arbitrary region between the second projection portions 46A and 46C on the one side and on the inward side toward the first trench structure 30A.

In other words, the plurality of trench connection structures 50 electrically connect the second gate electrode 44 on the one side to the gate electrode 34 adjoining in the first direction X. In this embodiment, the plurality of trench connection structures 50 are each arranged at a position close to the second projection portion 46C on the inward side with respect to the second projection portion 46B on the one side. In this embodiment, the plurality of trench connection structures 50 are each arranged on the same line extending in the second direction Y.

In this embodiment, the plurality of source regions 60 are each formed in a region on the one side (first-second projection portion 36A-46A side) and in a region on the other side (first-second projection portion 36B-46B side) with respect to the plurality of trench connection structures 50. The plurality of source regions 60 are connected to the first and second trench structures 30A and 30B in the first direction X, and are formed at a distance from the plurality of trench connection structures 50 in the second direction Y.

In this embodiment, the plurality of contact holes 61 are each formed in a region on the one side (first-second projection portion 36A-46A side) and in a region on the other side (first-second projection portion 36B-46B side) with respect to the plurality of trench connection structures 50. The plurality of contact holes 61 are formed at a distance from the first and second trench structures 30A and 30B in the first direction X, and are formed at a distance from the plurality of trench connection structures 50 in the second direction Y.

The plurality of second source via electrodes 72 include the second source via electrodes 72A and 72C on the one side and on the inward side that are connected to the second projection portions 46A and 46C on the one side and on the inward side, respectively. In this embodiment, the plurality of second source via electrodes 72 do not include the second source via electrode 72B on the other side connected to the second projection portion 46B on the other side. The plurality of second source via electrodes 72C on the inward side are each connected to the second projection portion 46C on the inward side that corresponds in one-to-one correspondence. The plurality of second source via electrodes 72C on the inward side are arranged at a distance from each other in the first direction X, and face each other in the first direction X.

The plurality of second source via electrodes 72C on the inward side may be each connected to the second projection portion 46C on the inward side that corresponds in one-to-many correspondence. The plurality of second source via electrodes 72C on the inward side are not necessarily required to be arranged on the same line extending in the first direction X in a plan view, and may be arranged so as to deviate from each other in the second direction Y. The plurality of second source via electrodes 72C on the inward side face the gate electrode 34 adjoining in the first direction X in a plan view, and do not face the pair of first projection portions 36A and 36B.

In this embodiment, the plurality of gate via electrodes 74 are each connected to the first gate electrode 34 and to the second gate electrode 44 on the other side, and are not connected to the second gate electrode 44 on the one side. The plurality of gate via electrodes 74 are electrically connected to the second gate electrode 44 on the one side through the first gate electrode 34 and through the gate connection electrode 54.

The plurality of gate via electrodes 74 are arranged at a distance from each other in the first direction X, and face each other in the first direction X. The plurality of gate via electrodes 74 may be each connected to each of the first gate electrodes 34 and to each of the second gate electrodes 44 in one-to-many correspondence. The plurality of gate via electrodes 74 are not necessarily required to be arranged on the same line extending in the first direction X in a plan view, and may be arranged so as to deviate from each other in the second direction Y.

The plurality of gate via electrodes 74 are arranged at a position close to the first and second projection portions 36B and 46B on the other side with respect to the trench connection structure 50 in a plan view. In other words, the plurality of gate via electrodes 74 are each connected to the first gate electrode 34 and to the second gate electrode 44 on the other side so that the distance with respect to the first and second projection portions 36B and 46B on the other side becomes less than the distance with respect to the trench connection structure 50. The plurality of gate via electrodes 74 face the first gate electrode 34 and the second gate electrode 44 on the other side in the first direction X, and do not face the first and second projection portions 36B and 46B on the other side.

In this embodiment, the gate finger electrode 80b of the gate wiring electrode 80 overlaps with the plurality of separation electrodes 23, the plurality of first gate electrodes 34, the plurality of first projection portions 36B on the other side, the plurality of second gate electrodes 44 on the other side, and the plurality of second projection portions 46B on the other side in a plan view.

The gate finger electrode 80b is connected to the plurality of gate via electrodes 74. A gate potential applied to the gate pad electrode 80a is transmitted to the plurality of first gate electrodes 34 and to the plurality of second gate electrodes 44 on the other side through the gate finger electrode 80b and through the plurality of gate via electrodes 74. A gate potential applied to the plurality of first gate electrodes 34 is transmitted to the plurality of second gate electrodes 44 on the one side through the plurality of trench connection structures 50.

In this embodiment, the source pad electrode 81a of the source wiring electrode 81 overlaps with the plurality of first gate electrodes 34, the plurality of first projection portions 36A on the one side, the plurality of second gate electrodes 44, and the plurality of second projection portions 46A on the one side in a plan view, and does not overlap with the plurality of first projection portions 36B on the other side and the plurality of second projection portions 46B on the other side. The source pad electrode 81a is connected to the plurality of first to third source via electrodes 71 to 73. A source potential applied to the source pad electrode 81a is transmitted to the plurality of separation electrodes 23, the plurality of first source electrodes 33, the plurality of second source electrodes 43, and the plurality of source regions 60 through the plurality of first to third source via electrodes 71 to 73.

As described above, with the semiconductor device 1B, the same effect as the effect described with respect to the semiconductor device 1A is fulfilled in a relationship between the second projection portion 46A on the one side and the second projection portion 46C on the inward side (other side) and in a relationship between the second source via electrodes 72A and 72C on the one side and on the inward side (other side).

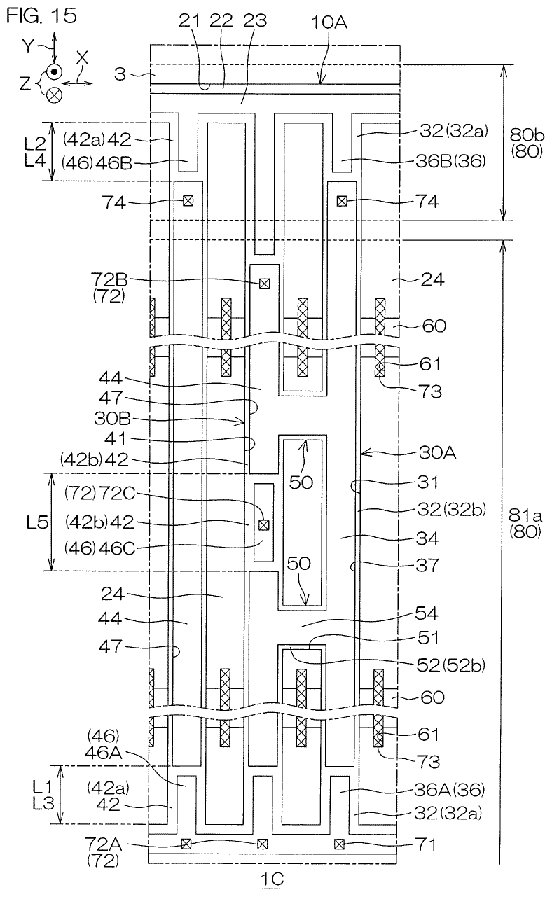

FIG. 15 corresponds to FIG. 14, and is a plan view showing a structure of the first main surface 3 of the chip 2 of a semiconductor device 1C according to a third embodiment. In the semiconductor device 1B according to the second embodiment, the second trench structure 30B includes the second projection portion 46B on the other side that faces the first projection portion 36B on the other side and that does not face the first gate electrode 34. On the other hand, in the semiconductor device 1C according to the third embodiment, the second trench structure 30B includes the second projection portion 46B on the other side that faces both the first projection portion 36B on the other side and the first gate electrode 34 in the same way as in the first embodiment.

The plurality of trench connection structures 50 are each pulled out from an arbitrary region between the pair of second projection portions 46A and 46C and an arbitrary region between the pair of second projection portions 46B and 46C of the second trench structure 30B toward an arbitrary region between the pair of first projection portions 36A and 36B of the adjacent first trench structure 30A.

In other words, the plurality of trench connection structures 50 electrically connect each of the second gate electrodes 44 on the one side and on the other side to the first gate electrode 34 adjoining in the first direction X. In this embodiment, the plurality of trench connection structures 50 are each arranged at a position close to the second projection portion 46C on the inward side with respect to the second projection portions 46A and 46B on the one side and on the other side. In this embodiment, the plurality of trench connection structures 50 are each arranged on the same line extending in the second direction Y in a plan view.

In this embodiment, the plurality of second source via electrodes 72 include the plurality of second source via electrodes 72A to 72C on the one side, on the other side, and on the inward side that are connected to the plurality of second projection portions 46A to 46C, respectively. In this embodiment, the plurality of gate via electrodes 74 are not connected to the second gate electrodes 44 on the one side and on the other side. The gate finger electrode 80b of the gate wiring electrode 80 is connected to the first gate electrode 34 through the plurality of gate via electrodes 74.

A gate potential applied to the gate pad electrode 80a is transmitted to the plurality of first gate electrodes 34 through the gate finger electrode 80b and through the plurality of gate via electrodes 74. A gate potential applied to the plurality of first gate electrodes 34 is transmitted to the second gate electrodes 44 on the one side and on the other side through the plurality of trench connection structures 50. The source pad electrode 81a of the source wiring electrode 81 is electrically connected to the plurality of second projection portions 46A to 46C through the plurality of second source via electrodes 72A to 72C.

As described above, with the semiconductor device 1C, the same effect as the effect described with respect to the semiconductor device 1A is fulfilled in a relationship between the plurality of second projection portions 46A to 46C and in a relationship between the plurality of second source via electrodes 72A to 72C.

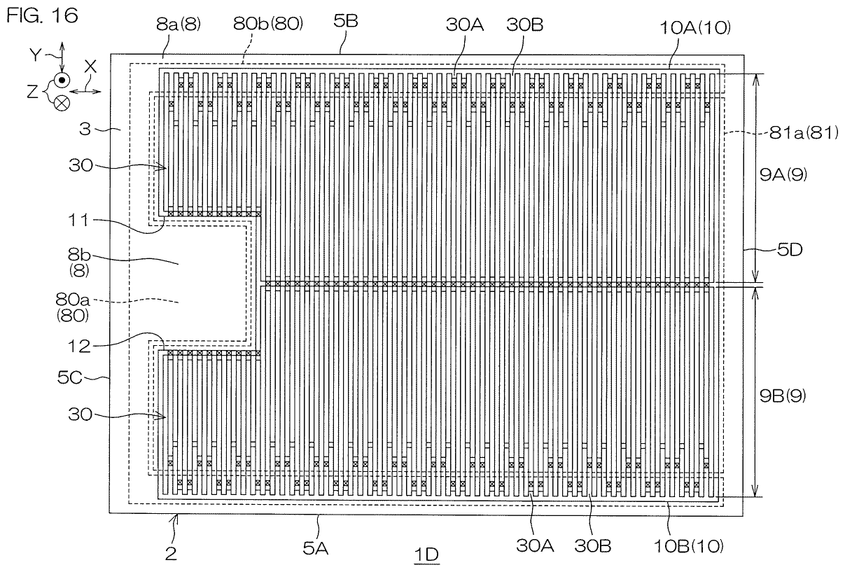

FIG. 16 corresponds to FIG. 2, and is a plan view showing a structure of the first main surface 3 of the chip 2 of a semiconductor device 1D according to a fourth embodiment. Referring to FIG. 16, the semiconductor device 1D according to the fourth embodiment includes the second trench separation structure 10B formed integrally with the first trench separation structure 10A in a region between the first device region 9A and the second device region 9B. The separation electrode 23 placed at the connection portion between the first and second trench separation structures 10A and 10B corresponds to a structure in which the second projection portion 46C on the inward side according to the second and third embodiments is connected to the plurality of trench structures 30 adjoining each other.

The plurality of first trench structures 30A on the second device region 9B side are connected to the plurality of first trench structures 30A on the first device region 9A side, respectively, through the connection portion between the first and second trench separation structures 10A and 10B. In other words, each of the first trench structures 30A on the second device region 9B side forms the first trench structure 30A integrally united with each of the first trench structures 30A on the first device region 9A side.

The first projection portion 36A on the one side (first side surface 5A side) of the integrally-united first trench structure 30A corresponds to the first projection portion 36A on the one side of the first trench structure 30A on the second device region 9B side. The first projection portion 36B on the other side (second side surface 5B side) of the integrally-united first trench structure 30A corresponds to the first projection portion 36B on the other side of the first trench structure 30A on the first device region 9A side.

The plurality of second trench structures 30B on the second device region 9B side are connected to the plurality of second trench structures 30B on the first device region 9A side, respectively, through the connection portion between the first and second trench separation structures 10A and 10B. In other words, each of the second trench structures 30B on the second device region 9B side forms the second trench structure 30B integrally united with each of the second trench structures 30B on the first device region 9A side.

The second projection portion 46A on the one side (first side surface 5A side) of the integrally-united second trench structure 30B corresponds to the second projection portion 46B on the one side of the second trench structure 30B on the second device region 9B side. The second projection portion 46B on the other side (second side surface 5B side) of the integrally-united second trench structure 30B is the second projection portion 46B on the other side of the second trench structure 30B on the first device region 9A side.

The gate wiring electrode 80 overlaps with both of the first projection portions 36A and 36B on the one side and on the other side of the integrally-united first trench structure 30A in a plan view. Also, the gate wiring electrode 80 overlaps with both of the second projection portions 46A and 46B on the one side and on the other side of the integrally-united second trench structure 30B in a plan view.

As described above, with the semiconductor device 1D, the same effect as the effect described with respect to the semiconductor device 1A is likewise fulfilled.

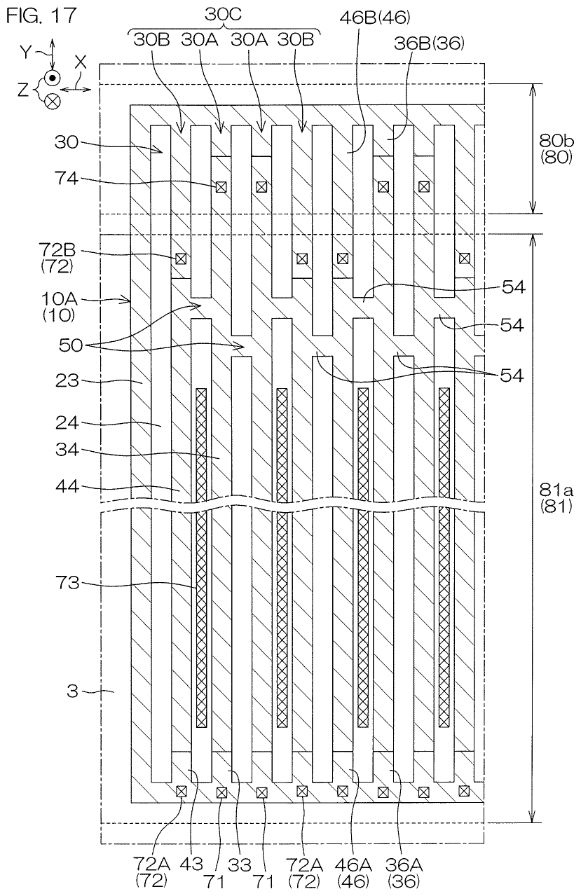

FIG. 17 corresponds to FIG. 3, and is a plan view showing a modification of the plurality of trench connection structures 50. The plurality of trench connection structures 50 according to the modification are applied to any one of the first to fourth embodiments. Referring to FIG. 17, each of the trench connection structures 50 may connect the plurality of trench structures 30 adjoining each other together. Preferably, in this case, the plurality of trench connection structures 50 is formed to deviate from each other in the second direction Y so as not to be arranged on the same line extending in the first direction X.

In other words, preferably, the plurality of trench connection structures 50 form a T-shaped junction portion with the corresponding first trench structure 30A in a plan view, and are connected to the corresponding first trench structure 30A so as not to form a crossroad portion. Also, preferably, the plurality of trench connection structures 50 form a T-shaped junction portion with the corresponding second trench structure 30B in a plan view, and are connected to the corresponding second trench structure 30B so as not to form a crossroad portion.

The trench connection structure 50 forming the T-shaped junction portion makes it possible to improve the embeddability of the first gate electrode 34, the second gate electrode 44, and the gate connection electrode 54. As a matter of course, the plurality of trench connection structures 50 may be connected to the first trench structure 30A and/or the second trench structure 30B so as to form a crossroad portion.

The connection aspect of the plurality of trench connection structures 50 varies according to the arrangement pattern of the plurality of first trench structures 30A and the plurality of second trench structures 30B. In this embodiment, the plurality of trench connection structures 50 connect the first and second trench structures 30A and 30B adjoining each other together. Also, the plurality of trench connection structures 50 connect the pair of first trench structures 30A adjoining each other together. Also, the plurality of trench connection structures 50 connect the pair of second trench structures 30A adjoining each other together.

The connection trench 51, the connection insulating film 52, the source connection electrode 53, the gate connection electrode 54, and the intermediate connection insulating film 55 of the plurality of trench connection structures 50 are connected to the first trench 31, the first insulating film 32, the first source electrode 33, the first gate electrode 34, and the first intermediate insulating film 35 of the first trench structure 30A in the same way as in each of the embodiments mentioned above. Also, the connection trench 51, the connection insulating film 52, the source connection electrode 53, the gate connection electrode 54, and the intermediate connection insulating film 55 of the plurality of trench connection structures 50 are connected to the second trench 41, the second insulating film 42, the second source electrode 43, the second gate electrode 44, and the second intermediate insulating film 45 of the second trench structure 30B in the same way as in each of the embodiments mentioned above.

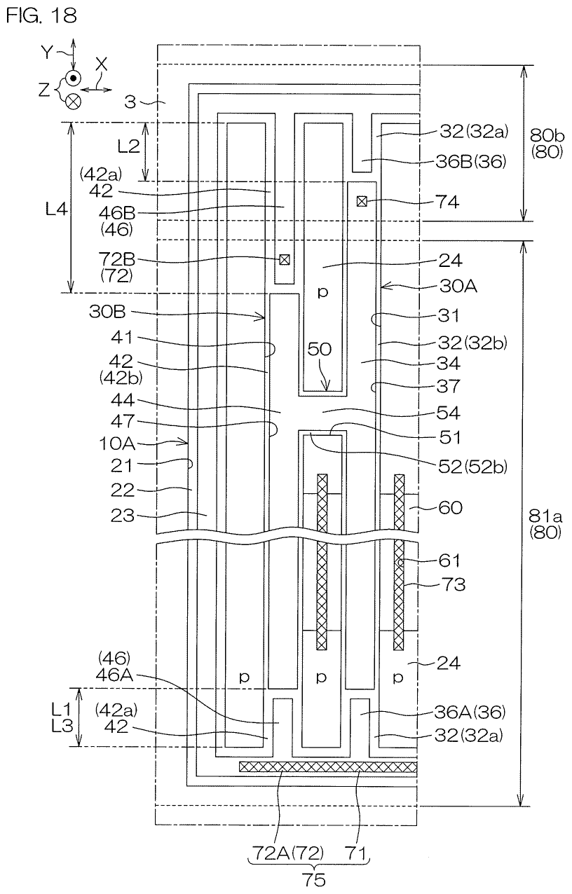

FIG. 18 corresponds to FIG. 4, and is a plan view showing a modification of the plurality of first source via electrodes 71 and the plurality of second source via electrodes 72. The plurality of first source via electrodes 71 and the plurality of second source via electrodes 72 according to the modification are applied to any one of the first to fourth embodiments. Referring to FIG. 18, the plurality of second source via electrodes 72 may be formed integrally with the plurality of first source via electrodes 71.

In other words, the first source via electrode 71 and the second source via electrode 72 may form an integrally-united source via electrode 75 that is electrically connected to both of the first and second projection portions 36A and 46A on the one side. The integrally-united source via electrode 75 may be formed in a band shape extending along the separation electrode 23.

Each of the embodiments mentioned above can be carried out in still other modes. A configuration example including the trench separation structure 10 (first and second trench separation structures 10A and 10B) is shown as described in each of the above embodiments. However, the trench separation structure 10 is not necessarily required, and may be removed.

A configuration example including the plurality of source regions 60 formed at a distance from the plurality of trench connection structures 50 in the second direction Y is shown as described in each of the above embodiments. However, the plurality of source regions 60 may be connected to the plurality of trench connection structures 50 in the second direction Y. In other words, the plurality of source regions 60 may form a channel controlled by the plurality of trench connection structures 50 between the second semiconductor region 7 and the source region 60.

A configuration example including the gate wiring electrode 80 that is a component structurally-independent of the plurality of gate via electrodes 74 is shown as described in each of the above embodiments. However, a part of the gate wiring electrode 80 may be formed as the plurality of gate via electrodes 74. In other words, the gate wiring electrode 80 may include the plurality of gate via electrodes 74 passing through the main surface insulating film 70.

A configuration example including the source wiring electrode 81 that is a component structurally-independent of the plurality of first to third source via electrodes 71 to 73 is shown as described in each of the above embodiments. However, a part of the source wiring electrode 81 may be formed as the plurality of first to third source via electrodes 71 to 73 passing through the main surface insulating film 70. In other words, the source wiring electrode 81 may include the plurality of first to third source via electrodes 71 to 73 passing through the main surface insulating film 70.

The “first conductivity type” is an “n-type,” and the “second conductivity type” is a “p-type” as described in each of the embodiments mentioned above. However, the “first conductivity type” may be a “p-type,” and the “second conductivity type” may be an “n-type.” The concrete configuration in this case can be obtained by replacing the “n-type region” with a “p-type region” and by replacing the “n-type region” with a “p-type region” in the foregoing description and the accompanying drawings.

Features of the first to fourth embodiments mentioned above can be combined together in an arbitrary manner between these embodiments, and the semiconductor devices 1A to 1D each of which concurrently includes at least two features among the features of the first to fourth embodiments may be employed. In other words, the feature of the second embodiment may be combined with the feature of the first embodiment. Also, the feature of the third embodiment may be combined with either one of the features of the first and second embodiments. Also, the feature of the fourth embodiment may be combined with any one of the features of the first to third embodiments.

Examples of features extracted from this description and from the drawings will be hereinafter shown. The following [A1] to [A20] provide a semiconductor device having appropriate source resistance.

[A1] A semiconductor device comprising: a chip having a main surface; a trench structure including a trench formed at the main surface, a source electrode that is embedded in the trench at a bottom side of the trench and that has a projection portion on one side and a projection portion on the other side both of which protrude toward an opening side of the trench, and a gate electrode embedded between a pair of the projection portions at the opening side of the trench; and a source via electrode on one side and a source via electrode on the other side that are connected to the projection portion on the one side and the projection portion on the other side, respectively, on the trench structure.

[A2] The semiconductor device according to A1, wherein the semiconductor device does not have a gate via electrode connected to the gate electrode on the trench structure.

[A3] The semiconductor device according to A1 or A2, further comprising: a gate wiring electrode arranged above the trench structure so as not to overlap with the gate electrode in a plan view; and a source wiring electrode that is arranged above the trench structure so as to overlap with the pair of the projection portions and with the gate electrode in a plan view and that is connected to a pair of the source via electrodes.

[A4] The semiconductor device according to A3, wherein the source wiring electrode overlaps with a whole area of the gate electrode in a plan view.

[A5] The semiconductor device according to A3 or A4, wherein the gate wiring electrode overlaps with either one or both of the pair of the projection portions in a plan view.

[A6] The semiconductor device according to any one of A1 to A5, further comprising: a trench connection structure including a connection trench formed at the main surface so as to communicate with the trench and a gate connection electrode embedded in the connection trench so as to be connected to the gate electrode.

[A7] The semiconductor device according to A6, wherein the gate connection electrode imparts a gate potential to the gate electrode.

[A8] The semiconductor device according to A6 or A7, further comprising: a source connection electrode embedded in the connection trench at a bottom side of the connection trench so as to be connected to the source electrode; wherein the gate connection electrode is embedded in the connection trench at an opening side of the connection trench.

[A9] The semiconductor device according to A8, wherein the gate connection electrode faces a whole area of the source connection electrode in a plan view.

[A10] The semiconductor device according to any one of A1 to A9, wherein the projection portion on the other side is longer than the projection portion on the one side.

[A11] The semiconductor device according to A10, wherein the source via electrode on the other side is connected to the projection portion on the other side at a position close to the gate electrode.

[A12] A semiconductor device comprising a chip having a main surface; a first trench structure including a first trench formed at the main surface, a first source electrode that is embedded in the first trench at a bottom side of the first trench and that has a first projection portion on one side and a first projection portion on the other side both of which protrude toward an opening side of the first trench, and a first gate electrode embedded between a pair of the first projection portions at the opening side of the first trench; a second trench structure including a second trench that adjoins the first trench and that is formed at the main surface, a second source electrode that is embedded in the second trench at a bottom side of the second trench and that has a second projection portion on one side and a second projection portion on the other side both of which protrude toward an opening side of the second trench, and a second gate electrode embedded between a pair of the second projection portions at the opening side of the second trench; a first source via electrode connected to the first projection portion on the one side on the first trench structure; a second source via electrode on one side and a second source via electrode on the other side that are connected to the second projection portion on the one side and the second projection portion on the other side, respectively, on the second trench structure; and a gate via electrode connected to the first gate electrode on the first trench structure.

[A13] The semiconductor device according to A12, wherein the semiconductor device does not have a gate via electrode connected to the second gate electrode on the second trench structure.

[A14] The semiconductor device according to A12 or A13, further comprising: a gate wiring electrode that is arranged above the first trench structure so as to overlap with the first gate electrode in a plan view and that is connected to the gate via electrode; and a source wiring electrode that is arranged above the first trench structure and above the second trench structure so as to overlap with the first projection portion on the one side and with the pair of the second projection portions in a plan view and that is connected to the first source via electrode and to a pair of the second source via electrodes.

[A15] The semiconductor device according to A14, wherein the gate wiring electrode does not overlap with the second gate electrode in a plan view, and the source wiring electrode overlaps with the first gate electrode and with the second gate electrode in a plan view.

[A16] The semiconductor device according to A14 or A15, wherein the source wiring electrode overlaps with a whole area of the second gate electrode in a plan view.

[A17] The semiconductor device according to any one of A12 to A16, further comprising: a trench connection structure including a connection trench formed at the main surface so as to communicate with the first trench and with the second trench and a gate connection electrode embedded in the connection trench so as to be connected to the first gate electrode and to the second gate electrode.

[A18] The semiconductor device according to A17, further comprising: a source connection electrode embedded in the connection trench at a bottom side of the connection trench so as to be connected to the first source electrode and to the second source electrode; wherein the gate connection electrode is embedded in the connection trench at an opening side of the connection trench.

[A19] The semiconductor device according to any one of A12 to A18, wherein the second projection portion on the one side faces the first projection portion on the one side across a part of the chip, and the second projection portion on the other side faces the first projection portion on the other side and the first gate electrode across a part of the chip.

[A20] The semiconductor device according to A19, wherein the second source via electrode on the other side is connected to the second projection portion on the other side at a position close to the second gate electrode.

Although the embodiments have been described in detail, these embodiments are merely concrete examples used to clarify the technical contents, and the present invention should not be interpreted by being limited to these specific examples, and the scope of the present invention is limited by the appended claims.

What is claimed is:

1. A semiconductor device comprising:
a chip having a main surface;
a groove structure including a groove formed at the main surface, a source electrode that is embedded in the groove at a bottom side of the groove and that has a projection portion on one side and a projection portion on the other side both of which protrude toward an opening side of the groove, and a gate electrode embedded between a pair of the projection portions at the opening side of the groove; and
a source via electrode on one side and a source via electrode on the other side that are connected to the projection portion on the one side and the projection portion on the other side, respectively, on the groove structure.

2. The semiconductor device according to claim 1,
wherein the semiconductor device does not have a gate via electrode connected to the gate electrode on the groove structure.

3. The semiconductor device according to claim 1, further comprising:
a gate wiring arranged above the groove structure so as not to overlap with the gate electrode in a plan view; and
a source wiring that is arranged above the groove structure so as to overlap with the pair of the projection portions and with the gate electrode in a plan view and that is connected to a pair of the source via electrodes.

4. The semiconductor device according to claim 3,
wherein the source wiring overlaps with a whole area of the gate electrode in a plan view.

5. The semiconductor device according to claim 3,
wherein the gate wiring overlaps with either one or both of the pair of the projection portions in a plan view.

6. The semiconductor device according to claim 1, further comprising:
a groove connection structure including a connection groove formed at the main surface so as to communicate with the groove and a gate connection electrode embedded in the connection groove so as to be connected to the gate electrode.

7. The semiconductor device according to claim 6,
wherein the gate connection electrode imparts a gate potential to the gate electrode.

8. The semiconductor device according to claim 6, further comprising:
a source connection electrode embedded in the connection groove at a bottom side of the connection groove so as to be connected to the source electrode;
wherein the gate connection electrode is embedded in the connection groove at an opening side of the connection groove.

9. The semiconductor device according to claim 8,
wherein the gate connection electrode faces a whole area of the source connection electrode in a plan view.

10. The semiconductor device according to claim 1,
wherein the projection portion on the other side is longer than the projection portion on the one side.

11. The semiconductor device according to claim 10,
wherein the source via electrode on the other side is connected to the projection portion on the other side at a position close to the gate electrode.

12. A semiconductor device comprising:
a chip having a main surface;
a first groove structure including a first groove formed at the main surface, a first source electrode that is embedded in the first groove at a bottom side of the first groove and that has a first projection portion on one side and a first projection portion on the other side both of which protrude toward an opening side of the first groove, and a first gate electrode embedded between a pair of the first projection portions at the opening side of the first groove;
a second groove structure including a second groove that adjoins the first groove and that is formed at the main surface, a second source electrode that is embedded in the second groove at a bottom side of the second groove and that has a second projection portion on one side and a second projection portion on the other side both of which protrude toward an opening side of the second groove, and a second gate electrode embedded between a pair of the second projection portions at the opening side of the second groove;
a first source via electrode connected to the first projection portion on the one side on the first groove structure;
a second source via electrode on one side and a second source via electrode on the other side that are connected to the second projection portion on the one side and the second projection portion on the other side, respectively, on the second groove structure; and
a gate via electrode connected to the first gate electrode on the first groove structure.

13. The semiconductor device according to claim 12,
wherein the semiconductor device does not have a gate via electrode connected to the second gate electrode on the second groove structure.

14. The semiconductor device according to claim 12, further comprising:
a gate wiring that is arranged above the first groove structure so as to overlap with the first gate electrode in a plan view and that is connected to the gate via electrode; and
a source wiring that is arranged above the first groove structure and above the second groove structure so as to overlap with the first projection portion on the one side and with the pair of the second projection portions in a plan view and that is connected to the first source via electrode and to a pair of the second source via electrodes.

15. The semiconductor device according to claim 14, wherein
the gate wiring does not overlap with the second gate electrode in a plan view, and
the source wiring overlaps with the first gate electrode and with the second gate electrode in a plan view.

16. The semiconductor device according to claim 14,
wherein the source wiring overlaps with a whole area of the second gate electrode in a plan view.

17. The semiconductor device according to claim 12, further comprising:
a groove connection structure including a connection groove formed at the main surface so as to communicate with the first groove and with the second groove and a gate connection electrode embedded in the connection groove so as to be connected to the first gate electrode and to the second gate electrode.

18. The semiconductor device according to claim 17, further comprising:
a source connection electrode embedded in the connection groove at a bottom side of the connection groove so as to be connected to the first source electrode and to the second source electrode;
wherein the gate connection electrode is embedded in the connection groove at an opening side of the connection groove.

19. The semiconductor device according to claim 12,
wherein the second projection portion on the one side faces the first projection portion on the one side across a part of the chip, and
the second projection portion on the other side faces the first projection portion on the other side and the first gate electrode across a part of the chip.

20. The semiconductor device according to claim 19,
wherein the second source via electrode on the other side is connected to the second projection portion on the other side at a position close to the second gate electrode.
